(19) United States
(12) Patent Application Publication
(10) Pub. No.: US 2024/0219894 A1
(43) Pub. Date: Jul. 4, 2024

(54) METHODS AND APPARATUS TO DETECT DEFECTS DURING SEMICONDUCTOR CHIP FABRICATION AND/OR TO DEBUG SEMICONDUCTOR CHIPS AFTER FABRICATION

(71) Applicant: Intel Corporation, Santa Clara, CA (US)

(72) Inventors: Santosh Tripathi, Portland, OR (US); Tuyen Tran, Portland, OR (US)

(21) Appl. No.: 18/148,717

(22) Filed: Dec. 30, 2022

(51) Int. Cl. G05B 19/418; G01R 1/073; H01L 21/768

(52) U.S. Cl. CPC G05B 19/41875; G01R 1/07314; H01L 21/76898; G05B 2219/32222; H01L 22/12

(57) ABSTRACT

Methods, apparatus, systems, and articles of manufacture to detect defects during semiconductor chip fabrication and/or to debug semiconductor chips after fabrication are disclosed. An example apparatus includes a substrate, integrated circuitry on a first side of the substrate, and an array of pins extending through the substrate. The pins include first ends on the first side of the substrate and second ends protruding beyond a second side of the substrate opposite the first side.

### FIELD OF THE DISCLOSURE

This disclosure relates generally to semiconductor chip fabrication and, more particularly, to methods and apparatus to detect defects during semiconductor chip fabrication and/or to debug semiconductor chips after fabrication.

### BACKGROUND

The manufacture of an integrated circuit chip, beginning from a semiconductor wafer all the way to a packaged chip, can take months and often involves numerous fabrication processes. The numerous processes involved give rise to many opportunities for defects to develop. Such defects can be physical in nature (e.g., affecting the physical structure of the chip) and/or parametric in nature (e.g., affecting the electrical properties (e.g., resistance, capacitance, inductance, etc.) of circuits in the chip). While physical defects can often be detected at any point during the fabrication process, it is much more difficult to detect parametric defects until well into the fabrication process. Specifically, parametric defect detection is typically only available after completion of all front-end-of-line processing (e.g., after all transistors and other active semiconductor components are completely fabricated). Further, some parametric defects often cannot be detected until after or near the conclusion of all back-end-of-line processing (e.g., after all metal interconnects are provided to electrically couple the transistors and other active semiconductor components together).

### BRIEF DESCRIPTION OF THE DRAWINGS

FIG. 1 illustrates an example semiconductor inspection tool with an example electrical measurement probe in contact with a sample.

FIG. 2 is a perspective view of the example probe and sample of FIG. 1.

FIG. 3 illustrates an example process flow to detect the defect in the sample of FIG. 1.

FIG. 4 is a flowchart representative of an example method to manufacture the example probe of FIG. 1.

FIGS. 5-13 represent the example probe at various stages during the example method of manufacture set forth in FIG. 4.

FIG. 14 is a block diagram of the example defect detection controller of FIG. 1.

FIGS. 15-18 are flowcharts representative of example machine readable instructions and/or example operations that may be executed by example processor circuitry to implement the defect detection controller of FIG. 14.

FIG. 19 is a block diagram of an example processing platform including processor circuitry structured to execute the example machine readable instructions and/or the example operations of FIGS. 15-18 to implement the defect detection controller of FIG. 14.

FIG. 20 is a block diagram of an example implementation of the processor circuitry of FIG. 19.

FIG. 21 is a block diagram of another example implementation of the processor circuitry of FIG. 19.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Semiconductor fabrication process issues that are not discovered until integrated circuit chips (also referred to herein as semiconductor chips) are completely or nearly completely manufactured are extremely costly because they result in weeks or months of lost time during which the chips were being fabricated. Accordingly, testing procedures and equipment have been developed to detect defects as soon as possible during the fabrication process.

Physical defects can be detected in-line (during and/or between successive fabrication processes) using optical-based inspection tools and/or electron-beam-based inspection tools. Thus, some physical defects can be detected early on. However, there are limitations with both optical inspection tools and e-beam inspection tools. In particular, optical inspection tools are limited by the wavelength of light used with such tools and, therefore, cannot detect defects smaller than a threshold size. E-beam inspection technology can detect much smaller defects than optical inspection technology. However, e-beam inspection is limited to very small areas. Some e-beam inspection tools include multiple beams but they are still limited to relatively smaller areas and cannot practicably be used to inspect large areas (or an entire surface) of a semiconductor wafer repeatedly throughout a fabrication process because it would take too much time. Furthermore, both optical inspection and e-beam inspection are limited to inspecting the top surface of a sample such that defects internal to the sample (e.g., incomplete bonding of the underside of a layer of material deposited on an underlying layer of material) may go undetected. As used herein, the term “sample” refers to a semiconductor wafer and/or structural features fabricated on the wafer that are the subject of interest in a defect inspection process.

While the detection of physical defects (with some limitations noted above) are possible at different stages during the manufacture process of semiconductor chips, it is much harder to detect parametric defects (also referred to herein as electrical defects). As used herein, parametric defects are defects in the electrical properties and/or associated functions of electrical circuits in semiconductor chips. As used herein, electrical circuits include both active components (e.g., transistors) and passive components (e.g., metal interconnects or wiring between transistors, r resisters, capacitors, inductors, etc.). Electrical testing equipment is available to test the electrical properties and/or function of such components. However, such testing can only occur after the transistors are completely fabricated (e.g., at the conclusion of front-end-of-line (FEOL) processing) because existing testing equipment is designed to test completed circuits (typically involving multiple completely fabricated transistors interconnected by at least one metallization layer (provided near the beginning of BEOL processing)). As such, electrical testing is typically only available well into the fabrication process such that a significant amount of time and associated cost may be lost if a defect is discovered. Furthermore, testing at the conclusion of FEOL processing and/or soon thereafter (e.g., after a first metal layer is added to interconnect some transistors) is limited to the testing of circuits specifically completed for testing purposes. These specific circuits typically only cover a small area of a semiconductor chip because other transistors are not yet interconnected via wires fabricated during subsequent back-end-of-line (BEOL) processing. Therefore, testing at the conclusion of FEOL processing is limited to a small area on a chip that may not be representative of an entire wafer (on which many chips are being fabricated, each with millions or billions of transistors). Indeed, in many instances, the small areas containing the circuits that can be tested at or soon after completion of FEOL processing are positioned near the edge of semiconductor chips on a wafer and destroyed when the chips are separated (e.g., singulated) from each other before packaging.

As noted above, testing the operation, function, and/or electrical properties of multiple interconnected transistors in a circuit of multiple components can only occur after the relevant transistors are interconnected via metal provided during BEOL processing. This puts the detection of electrical defects at an even later point in time again contributing to the potential for significant losses in time and expense. Further still, the fully integrated circuit of all interconnected transistors cannot be tested until all metal interconnects are added (e.g., at the conclusion of BEOL processing).

Examples disclosed herein include a semiconductor inspection probe or tool and associated methods to detect parametric defects at any stage during the fabrication process (including before completion of front-end-of-line processing). As a result, electrical defect detection can occur much sooner in the fabrication than using other existing techniques for significant cost and time savings. Further, inasmuch as electrical properties are a function of the physical structure of components in a semiconductor chip, examples disclosed herein can also detect physical defects, including internal physical defects (e.g., defects that are below an outer surface of a sample) that may go undetected using traditional optical and/or e-beam based inspection techniques. Examples disclosed herein may replace the need for other inspection techniques. Alternatively, examples disclosed herein provide additional inspection techniques that can supplement and/or complement other inspection techniques. In addition to testing semiconductor chips during the fabrication process, examples disclosed herein can also be used to debug semiconductor chips after fabrication.

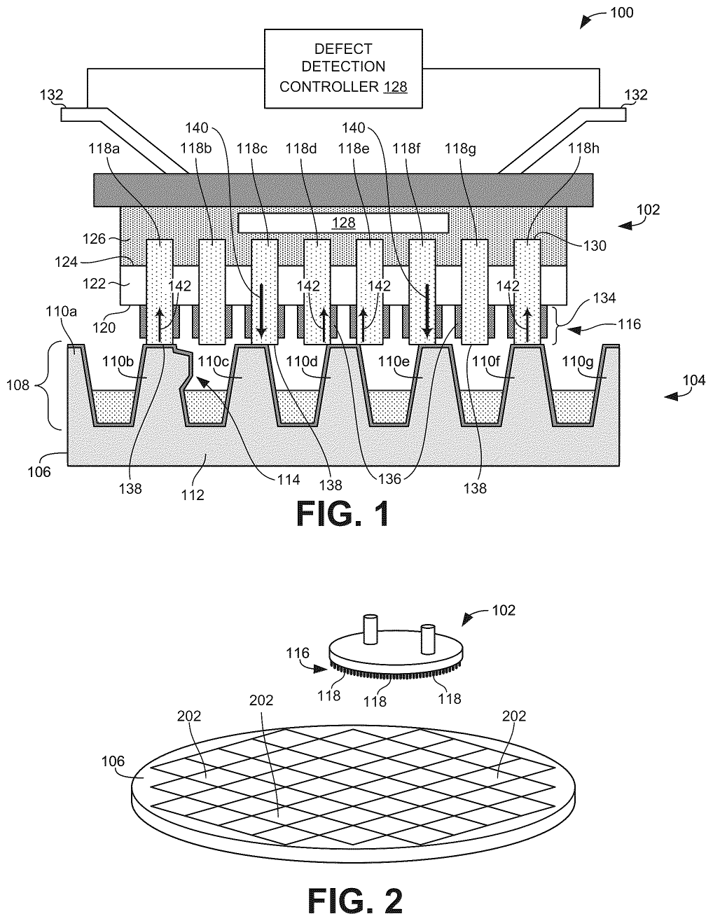

FIG. 1 illustrates an example semiconductor inspection tool 100 that includes an example electrical measurement probe 102. In the illustrated example, the probe 102 is in contact with a sample 104. In this example, the sample 104 (for which electrical properties are to be measured via the probe 102) corresponds to a semiconductor (e.g., silicon) substrate or wafer 106 with a plurality of different structural features 108 provided thereon. The particular shape of the structural features 108 shown in FIG. 1 is for purposes of illustration only and can include any type(s) of structures (e.g., pillars, fins, trenches, vias, holes, elongate traces or lines, flat plates, thin films, doped regions in a base substrate, etc.) of any suitable shape and any suitable size made using any suitable material (e.g., conductive materials (e.g., metal), semiconductor materials, dielectric materials, etc.). The structural features 108 are provided as a result of one or more fabrication processes implemented at any point during the manufacture of an integrated circuit including during either FEOL processing or during BEOL processing. FEOL processing involves fabrication processes associated with the creation of transistors and other active components in an integrated circuit. Thus, in some examples, the structural features 108 correspond to individual parts or components (e.g., a source, a drain, a gate, gate/source/drain contacts, etc.) of a transistor that is not yet completely fabricated. BEOL processing begins after the transistors are fabricated (during the FEOL) and involves the addition of metallization layers to define wiring and/or interconnects to electrically couple the transistors (previously fabricated during FEOL processing). Thus, in some examples, the structural features 108 correspond to metal interconnects (e.g., traces, vias, etc.) and/or dielectric materials disposed therebetween. Other active and/or passive components (e.g., resisters, capacitors, inductors, etc.) can be fabricated in either or both of the FEOL and BEOL processing periods.

For purposes of explanation, in the illustrated example of FIG. 1, the structural features 108 of the sample include an array of protrusions 110a, 110b, 110c, 110d, 110e, 110f, 110g extending from a base layer 112 of the semiconductor wafer 106. The fabrication processes used to create the protrusions 110a-g (collectively identified by the reference numeral 110) are not relevant to examples disclosed herein as any suitable fabrication processes may be used. For instance, in some examples, the protrusions 110a-g could be added (e.g., deposited, grown, etc.) onto the base layer 112. Alternatively, the protrusions 110a-g could be created by removing (e.g., etching) the material initially between the protrusions. In this example, each of the protrusions 110a-g is designed to have a same size and a same shape. However, as shown in the illustrated example, the second protrusion 110b includes a defect 114 that may be detected by the semiconductor inspection tool 100 in accordance with teachings disclosed herein. In this example, the defect 114 is an outcropping on one side of the second protrusion 110b from the left in the illustrated example of FIG. 1. However, the semiconductor inspection tool 100 can detect any type of defect that may affect the electrical properties of the structural features 108. Thus, example defects include excess material (e.g., the outcropping shown in FIG. 1), missing material (e.g., voids, pits, gaps between interfacing materials, incomplete coatings or films, etc.), contaminated materials, foreign particulates, overly rough surfaces, materials with uneven thicknesses, and/or any other types of defects.

As shown in FIG. 1, the probe 102 includes an array 116 of pins 118a, 118b, 118c, 118d, 118e, 118f, 118g, 118h (collectively identified by the reference numeral 118) that protrude beyond a first side or surface 120 of a substrate 122 toward the sample 104. In this example, the substrate 122 is a semiconductor substrate that includes silicon. However, any other suitable semiconductor may additionally or alternatively be used. In some examples, the substrate 122 is a dielectric. The array 116 of the illustrated example includes eight pins 118 in a row. However, in some examples, the array 116 of pins 118 is a two-dimensional array that includes a significantly greater number of pins than what is shown. More particularly, the number of pins 118 can number in the tens of thousands, the millions, the billions. or more. The large number of pins 118 is made possible because the pins 118 are fabricated to be relatively small and densely arranged with a relatively small pitch. More particularly, in some examples, the width or diameter of the pins 118 is between approximately 1 micrometer (um) and 10 nanometers (nm) or less. Thus, the width or diameter of the pins 118 can be less than 500 nm, less than 250 nm, less than 150 nm, less than 120 nm, less than 100 nm, less than 75 nm, less than 50 nm, less than 25 nm, etc. Further, in some examples, the pins 118 are spaced apart at a pitch between approximately 2 um and 20 nm or less. Thus, the pitch or spacing of the pins 118 can be less than 1 um, less than 750 nm, less than 500 nm, less than 250 nm, less than 150 nm, less than 100 nm, less than 50 nm, etc. The large number of small pins 118 arranged close together enables the testing of many relatively small features (e.g., individual transistors and/or parts of transistors) across a relatively large area.

In addition to the size and spacing of the individual pins 118, the total number of pins 118 implemented on the example probe 102 depends on the overall size of the probe 102 and the associated area of the probe across which the pins 118 are distributed. FIG. 2 is a perspective via of the example probe 102 of FIG. 1 represented relative to an entirety of the semiconductor wafer 106 that includes a plurality of semiconductor dies 202. In this example, the structural features 108 shown in FIG. 1 are structural features in a particular one of the dies 202. In some examples, the same structural features 108 are fabricated on more than one (e.g., all) of the dies 202 of the semiconductor wafer 106. As shown in the illustrated example of FIG. 1, the probe 102 (and the associated array 116 of pins 118) is dimensioned to be larger than a single one of the dies 202. As such, in the illustrated example, the probe 102 can electrically test and/or measure the characteristics of the structural features 108 in more than one die at a single point in time. That is, the probe electrical test or captures measurement data for multiple dies 202 simultaneously or concurrently. Significantly, the measurement date is captured at a resolution corresponding to the size and spacing of the pins, thereby providing millions or even billions of data points with which to reliably characterize the electrical properties of across on entire die 202. In some examples, the probe 102 and the associated array 116 of pins 118 are dimensioned to correspond to the size of the wafer 106 so that all of the dies 202 can be measured and/or tested at a single point in time. In other examples, the probe 102 and the associated array 116 of pins 118 are dimensioned to correspond to the size of a single one of the dies 202. In such examples, the probe 102 tests individual ones of the dies 202 at a time. Significantly, however, in such examples, the probe 102 can test the entire area of the particular die 202 currently being sampled or tested, which is not possible using e-beam inspection technology. In some examples, the probe 102 is dimensioned to be smaller than ones of the dies 202 such that the probe 102 tests less than all of a given die 202 at any one point in time. While the example probe 102 shown in FIG. 2 is circular in shape, in other examples, the probe 102 and the associated array 116 of pins 118 can be any suitable shape (e.g., square, rectangular, etc.)

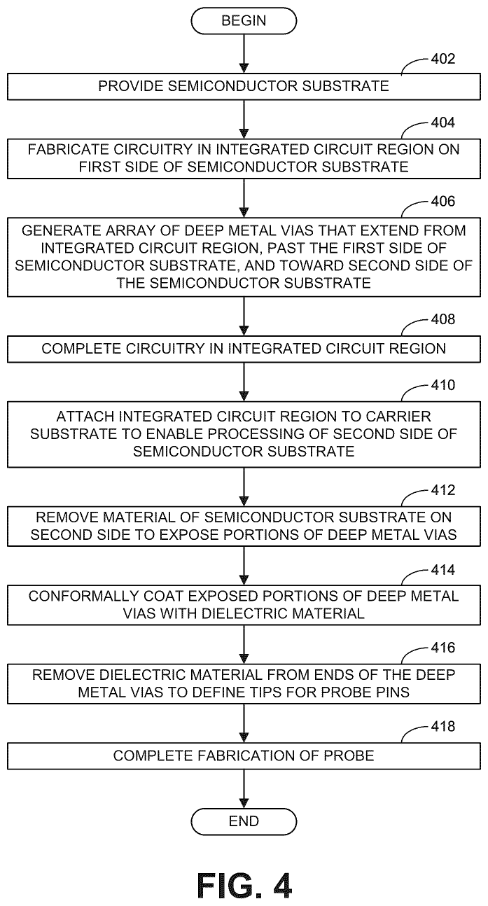

Returning to FIG. 1, in some examples, the pins 118 extend all the way through the substrate 122 and beyond a second surface 124 of the substrate 122 into an integrated circuit region 126 of the probe 102. The integrated circuit region 126 includes integrated circuit components that are electrically coupled to the pins 118. In some examples, the integrated circuit components in the integrated circuit region 126 are limited to passive components (e.g., metal wiring or interconnects). In some such examples, the substrate 122 is a dielectric substrate because there is no need to fabricate active components (e.g., transistors), typically fabricated on a semiconductor material. However, in some examples, the substrate 122 nevertheless includes a semiconductor. In some examples, the integrated circuit components include active components such as transistors. In some such examples, the substrate 122 corresponds to a bulk portion of a semiconductor wafer on which the integrated circuit components of the integrated circuit region 126 are fabricated as discussed further below in connection with FIGS. 4-13.

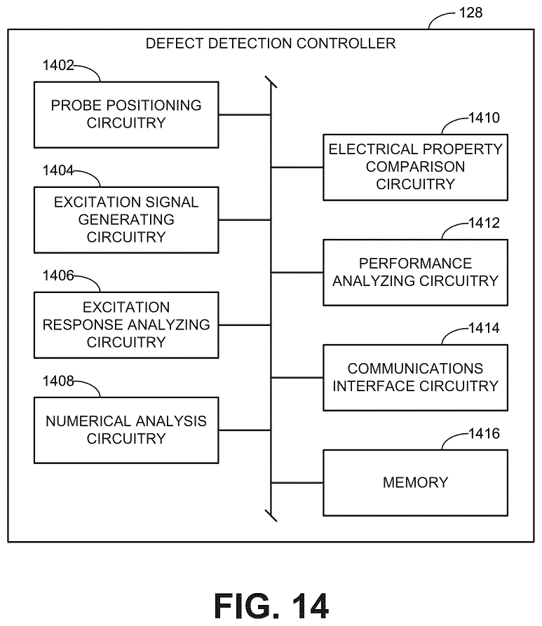

In some examples, the integrated circuit components in the integrated circuit region include and/or implement an example defect detection controller 128 that enables the operation and control of the probe 102 (and the associated pins 118) and/or the processing of measurement data captured using the probe 102. That is, in some examples, the defect detection controller 128 is monolithically integrated (e.g., as an application specific integrated circuit (ASIC)) on the substrate 122 through which the pins 118 extend. In the illustrated example, the defect detection controller 128 is shown as being farther away from the substrate 122 than proximate ends 130 of the pins are from the substrate 122. However, in some examples, some or all of the defect detection controller 128 is implemented within the portions of the integrated circuit region 126 between adjacent ones of the pins 118. Additionally or alternatively, in some examples, at least some of the defect detection controller 128 is implemented externally (as shown in FIG. 1) by a separate compute device (e.g., separate processor circuitry) communicatively coupled with the probe 102 via leads 132. While the defect detection controller 128 is shown both internal and external to the probe 102, in some examples, all functionality implemented by the defect detection controller 128 is implemented by integrated circuits within the integrated circuit region 126 of the probe 102. In other examples, all functionality implemented by the defect detection controller 128 is implemented external to and independent of the probe 102 (e.g., the integrated circuit region 126 is limited to passive circuit components). Further detail regarding the implementation of the defect detection controller 128 is provided below in connection with FIGS. 14-18.

In the illustrated example of FIG. 1, the portion 134 of the pins extending beyond the first surface 120 of the substrate 122 is surrounded or covered by a dielectric material 136. In some examples, the dielectric material includes silicon dioxide, silicon nitride, etc. In some examples, the dielectric material provides structural support for the protruding portions 134 of the pins 118, which could be relatively long relative to the width (e.g., diameter) of the pins 118. Specifically, in some examples, the length of the protruding portion 134 is greater than the width of the pins 118. In other examples, the length of the protruding portion 134 is less than or equal to the width of the pins 118. The length of the protruding portion 134 of the pins 118 can depend on the physical properties expected for the sample 104 being tested (e.g., whether the surface of the sample is even or uneven, the size and/or material of the features to which the pins 118 are to contact, etc.). Additionally or alternatively, in some examples, the dielectric material 136 serves to electrically isolate the pins 118 from one another to reduce the likelihood of a short circuit.

In some examples, while at least some (e.g., a majority) of the sidewall of the protruding portion 134 of the pins 118 is covered by the dielectric material 136, a distal end or tip 138 of the pins is uncovered or exposed. In this manner, the pins 118 can be positioned in direct contact with the structural features 108 on the sample 104 (as shown in FIG. 1) for purposes of conducting electrical measurements and tests. As noted above, the structural features 108 of the sample 104 can correspond to parts or components of transistors partially fabricated during ongoing FEOL processing. Typically, FEOL processing is designed to reduce (e.g., minimize) contamination of the transistors being fabricated. Accordingly, in some examples, the pins 118 are fabricated with a conductive material (e.g., metal) that is unlikely to contaminate the sample. For instance, in some examples, the pins 118 include cobalt (Co). However, other suitable material may alternatively be used (e.g., copper, aluminum, etc.). Further, in some examples, at least some of the pins 118 are non-conductive (e.g., include a high resistance dielectric) to take other types of electrical measures of the sample 104 (e.g., voltage stack measurements).

As shown in the illustrated example, it is not necessary for each of the pins 118 to contact a structural feature 108 on the sample 104. For instance, the second and seventh pins 118b, 118g, in the illustrated example, are aligned with the spaces between adjacent ones of the protrusions 110a-g and, therefore, are not in contact with any portion of the sample 104. Likewise, it is not necessary for each pin 118 to contact a different portion of the sample 104. For instance, in the illustrated example of FIG. 1, both the fourth and fifth pins 118d, 118e are in contact with the fourth protrusion 110d. In this example, the remaining first, third, sixth, and eighth pins 118a, 118c, 118f, 118h are in contact with the second, third, fifth, and sixth protrusions 110b, 110c, 110e, 110f, respectively. In some examples, the arrangement and/or spacing of the pins 118 can be specifically designed to match the arrangement of the structural features 108 to enable a one-to-one matching of pins 118 to structural features. However, as outlined above, this is not necessary. In some examples, the relatively densely packed array 116 of pins 118 enables the probe 102 to be positioned against structural features on a semiconductor having any design to characterize the electrical properties of the structural features. That is, in some examples, the same probe 102 can be used to measure different structural features on different semiconductor chips (and/or different parts of the same semiconductor chip). Moreover, the measurements made by the probe 102, as discussed further below, do not require the pins to align with specific contact pads on the sample 104 to be measured. Rather, the probe 102 can be positioned with the pins 118 contacting the sample 104 at any suitable location.

In some examples, to measure the electrical properties of the sample 104, an input or excitation signal 140 is applied, via one or more of the pins 118, to the structural features 108 in contact with the corresponding pins. For instance, both the third and sixth pins 118c, 118f are used to apply the excitation signal 140 as represented by the downward pointing arrows in the illustrated example. In some examples, the excitation signal 140 is applied via multiple pins 118 (e.g., both the third and sixth pins 118c, 118f) at the same time. In other examples, the excitation signal 140 may be applied via different (e.g., individual or groups of) pins 118 at different points in time in succession (e.g., first via the third pin 118c and then via the sixth pin 118f). The excitation signal 140 will pass through the structural features 108 of the sample 104 towards the other pins 118 in contact with the structural features 108 such that the other pins 118 are capable of capturing a response signal 142 that is a response to the excitation signal 140. In the illustrated example, the response signal 142 is captured by the first, third, sixth, and eighth pins 118a, 118c, 118f, 118h. The nature of the response signal 142 as detected or captured by each pin 118 depends upon the nature of the excitation signal as well as the physical characteristics of the structural features 108 in contact with the pins 118 and/or connected to and/or in contact with the structural features 108 in contact with the pins 118. That is, a different excitation signal 140 will result in a different response signal 142. However, even if the excitation signal 140 does not change, the resulting response signal 142 may change if there is a change in the characteristics (e.g., physical and/or electrical properties) of the structural features 108.

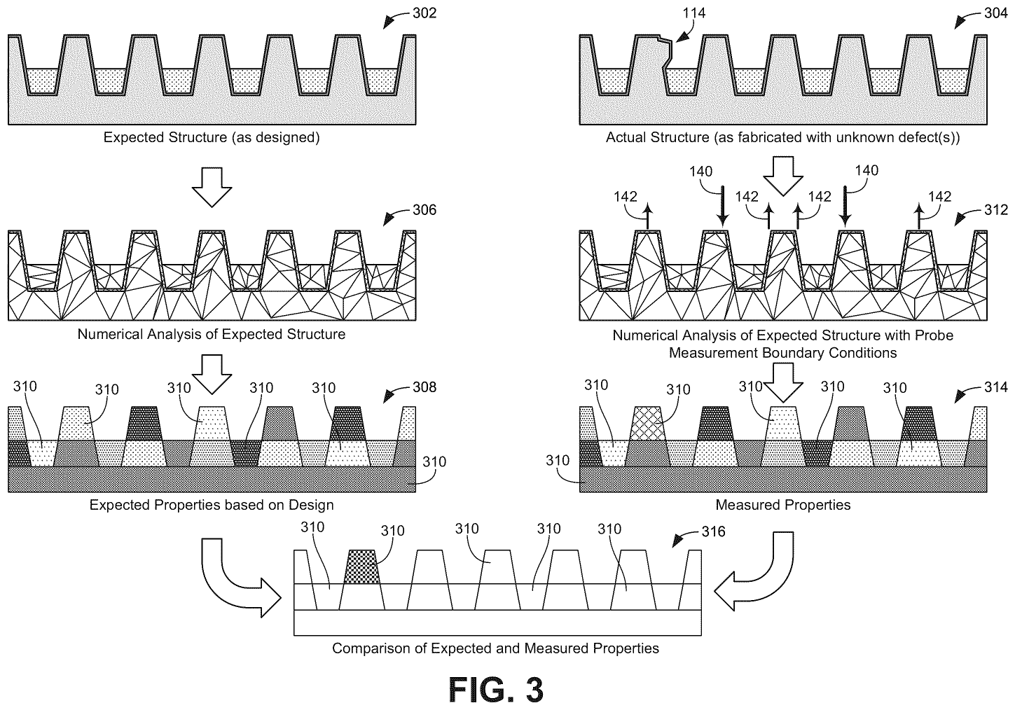

The example semiconductor inspection tool 100 is able to detect defects (such as the defect 114) based on the fact that changes to the structural features 108 of the sample 104 will result in changes to the response signal 142 for a given excitation signal 140. That is, if the structural features 108 of the sample 104 were fabricated without defect, the resulting response signal 142 would be different than the response signal 142 when captured with the defect 114 shown in FIG. 1. However, merely identifying a difference in response signals 142 is not sufficient to identify the nature and/or location of a particular defect. Accordingly, in some examples, electrical measurements are made to capture a response signal and the response signal is then used to characterize the electrical properties of particular portions or regions of the structural features 108. These measured or calculated electrical properties can then be compared to reference values (e.g., target values, expected values) for the electrical properties determined based on an intended or target design for the corresponding portions or regions of the structural features 108. This process is detailed in connection with FIG. 3.

FIG. 3 illustrates an example process flow to detect the defect 114 in the sample 104 of FIG. 1. The top image on the left-hand side of FIG. 3 represents an expected or expected structure 302 for the sample 104 of FIG. 1 being tested. The expected structure 302 is defined by the design of the physical layout of the components and structures to be fabricated on the semiconductor wafer 106. The top image on the right-hand side of FIG. 3 represents the actual structure 304 of the sample 104 of FIG. 1 being tested. The actual structure 304 is not known at the time of fabrication because it cannot be known whether defects or flaws developed during the processes involved in the fabrication. For this reason, testing and/or measurement with the semiconductor inspection tool 100 is employed to identify any such defects. In this instance, as shown in the illustrated example, it is a given that the actual structure 304 includes the defect 114. By contrast, the expected structure 302 does not include the defect 114.

The middle image on the left-hand side of FIG. 3 represents a first numerical analysis 306 of the expected structure 302 for the sample 104 of FIG. 1 being tested. The first numerical analysis 306 is performed based on the known physical layout of the expected structure 302 as well as the material properties used to fabricate the expected structure 302 to determine expected electrical properties or parameters (e.g., resistance, capacitance, inductance, etc.) of particular portions or regions of the expected structure 302. As used herein, the term “numerical analysis” refers to all current and future computational methods and their combinations that could be used to solve physics problems either accurately or approximately. Example numerical analyses include finite element analysis, finite difference time domain methods, ab initio methods, etc.

The bottom image on the left-hand side of FIG. 3 represents reference properties 308 (e.g., target properties, baseline properties, expected properties) for the expected structure 302 corresponding to outputs of the first numerical analysis 306. More particularly, as represented in the illustrated example, the reference properties 308 define reference or expected values for electrical properties or parameters for multiple individual portions or regions 310 of the expected structure 302. The regions 310 can be defined with any suitable size and or shape in accordance with the physical layout and design of the expected structure 302. For instance, in this example, different regions 310 are defined for upper and lower portions of the protrusions 110 in FIG. 1. In other examples, the protrusions 110 could be modeled by a single region 310 in the numerical analysis 306. In other examples, the protrusions 110 could be divided into more than two regions 310. By segmenting the structure through the numerical analysis in this manner, it is possible to determine the electrical properties of portions of the sample 104 underneath the upper surface, which is difficult or impossible to do with traditional optical and e-beam inspection technologies. Furthermore, this process does not rely on the specific flow of electricity or continuity of interconnects (as required by many traditional electrical testing) but can be applied to any structural features made with any type of materials positioned in relationship to any other structural features of any type of materials.

The different shading used for the different ones of the regions 310 in the reference properties 308 in FIG. 3 is for purposes of illustration to represent different values for the electrical properties associated with the respective regions 310. In some examples, multiple different values are calculated for each of multiple different electrical properties (e.g., one value for resistance, one value for capacitance, one value for inductance, etc.). In other examples, a single value is calculated for a particular region 310 to represent multiple different electrical properties for the particular region 310.

Like the first numerical analysis 306 on the left-hand side of FIG. 3, the middle image on the right-hand side of FIG. 3 represents a second numerical analysis 312 of the expected structure 302. Although the second numerical analysis 312 is intended to model the actual structure 304 that includes the defect 114, the expected structure 302 (without the defect 114) is used as the basis for the second numerical analysis 312 because the presence of the defect 114 is unknown. Though both numerical analyses 306, 312 are based on the same initial structure (e.g., the expected structure 302), the second numerical analysis 312 differs from the first numerical analysis 306 due to different boundary conditions. Specifically, the excitation signal 140 and corresponding response signal 142 from the electrical testing or measurement performed by the semiconductor inspection tool 100 of FIG. 1 are used as boundary conditions for the second numerical analysis 312. As discussed above, changes in the structural features 108 caused by defects 114 will result in a change in the response signal 142. As a result, while the expected structure 302 is used in the second numerical analysis 312, the presence of the defect 114 in the actual structure 304 is indirectly accounted for through the use of the excitation signal 140 and response signal 142 as boundary conditions.

The bottom image on the right-hand side of FIG. 3 represents measured properties 314 of the actual structure 304 corresponding to outputs of the second numerical analysis 312. As represented in the illustrated example, the measured properties 314 define values for electrical properties or parameters for the same regions 310 of the expected structure 302 defined by the reference properties 308. However, unlike the reference properties 308 that are theoretical based on the physical layout or design of the expected structure 302, the measured properties 314 are based on measurements taken using the probe 102. With both the reference properties 308 and the measured properties 314 defined for the same regions 310, it is possible to compare the reference properties 308 to the measured properties 314. If the actual structure 304 is fabricated without defect, the measured properties 314 should substantially match (e.g., within a threshold) the reference properties 308. Thus, as represented in FIG. 3, the shading in each corresponding region 310 of the reference properties 308 and the measured properties 314 match except at the location where the defect 114 is located on the actual structure 304 tested by the semiconductor inspection tool 100.

The center image at the bottom of FIG. 3 represents a comparison 316 of the reference properties 308 and the measured properties 314. More particularly, the comparison 316 represents a difference in the values determined for each respective region 310 defined by the reference properties 308 and the measured properties 314. In this example, the blank regions 310 in the comparison 316 correspond to regions in which the difference between the two sets of properties 308, 314 does not satisfy (e.g., is less than) a threshold. Thus, as shown in the comparison 316, only the region 310 corresponding to the location of the defect 114 has a difference that satisfies (e.g., exceeds) the threshold. While this difference does not necessarily define the physical characteristics (e.g., shape, material, etc.) of the defect 114, the difference indicates that a defect is likely at the specified location. Based on this information, semiconductor chip manufactures can take additional steps to investigate further to identify the nature of the defect (e.g., through optical and/or e-beam inspection technology) and/or decide to stop and/or adjust subsequent fabrication of the semiconductor wafer to avoid further defects and/or avoid costs associated with ongoing fabrication that will result in defective components.

The process flow outlined in FIG. 3 can be repeated multiple times throughout the fabrication process. In some examples, the measured properties (e.g., the measured properties 314) at a first point in time are used to generate the reference or baseline (e.g., the reference properties 308) to compare with additional measured properties captured at a second point in time later in the fabrication process. That is, in some examples, the expected structure at the second point in time is not strictly based on the original design of the physical layout (in which everything is idealized and it is assumed there are no defects). Rather, the expected structure at the second point in time in such examples is based on the measured properties at the first point. However, in some such examples, all structural features fabricated after the first point in time (up to the second point in time) are assumed to be idealized with the associated fabrication processes being performed without creating any defects (in accordance with the original design layout). In this manner, any defects in the actual structure 304 created before the first point in time will not confound the impact of measurements to detect defects that arise after the first point in time and before the second point in time. Additionally or alternatively, the parametric performance for a completed semiconductor chip can be predicted at any point in time while taking into account any defects detected up to that point in time by using the measured properties to characterize the structure up to the point in fabrication when the measurements were made and then to assume all subsequent processing does not introduce any further defects. In some examples, one or more defect(s) can be introduced into the subsequent processing could be incorporated into the analysis to determine the impact of such defects in conjunction with the previously detected defects up to the current point in the fabrication process.

In some examples, rather than comparing measured properties to reference properties (whether calculated from the design layout of a target structure or based on previous measurements), the semiconductor inspection tool 100 can be used to generate measure properties for multiple instances of the same structural features. For instance, as shown in FIG. 2, the semiconductor wafer 106 includes multiple different dies 202. Assuming each of the dies 202 is fabricated in the same manner and is based on the same physical layout, each die 202 should have the same structure as every other die during the fabrication process. Accordingly, in some examples, the semiconductor inspection tool 100 generates measured properties for structural features that are intended or expected to be common across two or more of the dies 202 and then compares those measured properties. If there is a difference between the measured properties that satisfies (e.g., exceeds) a threshold, that is an indication that there is a defect. In some such examples, the response signals 142 for each measurement can be compared directly without having to perform the numerical analysis, thereby reducing processing requirements and increasing efficiency.

The above approach of comparing different measured properties is not limited to comparing corresponding structural features at two different locations on a single wafer (e.g., two different dies 202). Rather, measurements can be taken from one semiconductor wafer and compared to measurements taken from a different semiconductor wafer. In some such examples, the reference measurements (to which other measured properties are compared) can be selected from a known good semiconductor chip that has completed the entire fabrication process and confirmed to work properly to use as a baseline when fabricating additionally instances of the same semiconductor chip (using the same fabrication processes).

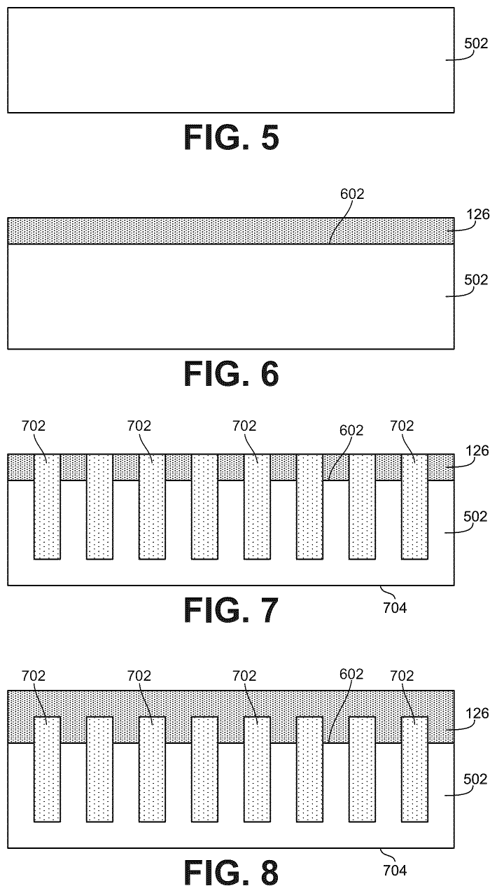

FIG. 4 is a flowchart representative of an example method to manufacture the example probe 102 of FIG. 1. Although the example method of manufacture is described with reference to the flowchart illustrated in FIG. 4, many other methods of manufacturing the example probe 102 may alternatively be used. For example, the order of execution of the blocks may be changed, and/or some of the blocks described may be changed, eliminated, or combined. Further, one or more additional operations may be implemented between any of the blocks shown in the flowchart. FIGS. 5-13 represent the example probe 102 at various stages during the manufacturing process set forth in FIG. 4.

The example method of FIG. 4 begins at block 402 by providing a substrate 502 as represented in FIG. 5. In some examples the substrate 502 is a semiconductor wafer (e.g., a silicon wafer). In other examples, the substrate 502 is a dielectric substrate. In this example, the substrate 502 serves as the basis for the substrate 122 in the probe 102 of FIG. 1.

At block 404, circuitry is fabricated in an integrated circuit region (e.g., the integrated circuit region 126 of FIG. 1) on a first side 602 of the substrate 502 as represented in FIG. 6. In this example, the first side 602 corresponds to the second surface 124 of the substrate 122 in the probe 102 of FIG. 1. As discussed above in connection with FIG. 1, in some examples, the integrated circuit region 126 is limited to passive components (e.g., metal interconnects and/or wiring) that enable the pins 118 of the probe 102 to be electrically coupled to an external controller (e.g., associated with the defect detection controller 128). In some examples, the integrated circuit region 126 includes active semiconductor components (e.g., transistors) that facilitate and/or enable the operation of the probe 102 and/or the analysis of the response signals 142 captured by the probe 102. In some such examples, as discussed above, the integrated circuit region 126 includes and/or implements the example defect detection controller 128 shown and described in connection with FIG. 1.

At block 406, an array of deep metal vias 702 are generated that extend from the integrated circuit region 126, past the first side 602 of the substrate 502, and toward a second side 704 of the substrate 502 as represented in FIG. 7. Fabrication of the metal vias 702 can be implemented in accordance with processes used to fabricate back-side power delivery in semiconductor chips. In this example, the deep metal vias serve as the basis for the individual pins 118 of the probe 102. Thus, as described above, the metal vias 702 (e.g., the pins 118) have a width that is relatively small (e.g., less than 1 um) and that are spaced at a pitch that is relatively small (e.g., less than 1 um). In some examples, one of more the vias 702 do not include metal but instead include a non-conductive material (e.g., a dielectric).

At block 408, the circuitry in the integrated circuit region 126 is completed as represented in FIG. 8. In some examples, the additional circuitry fabricated at this stage in the fabrication process includes metal interconnects electrically coupled to the individual metal vias 702 to enable the vias 702 to be used as the pins 118 in the probe 102 shown in FIG. 1. Further, as described above, in some examples, the additional circuitry may enable and/or implement the defect detection controller 128.

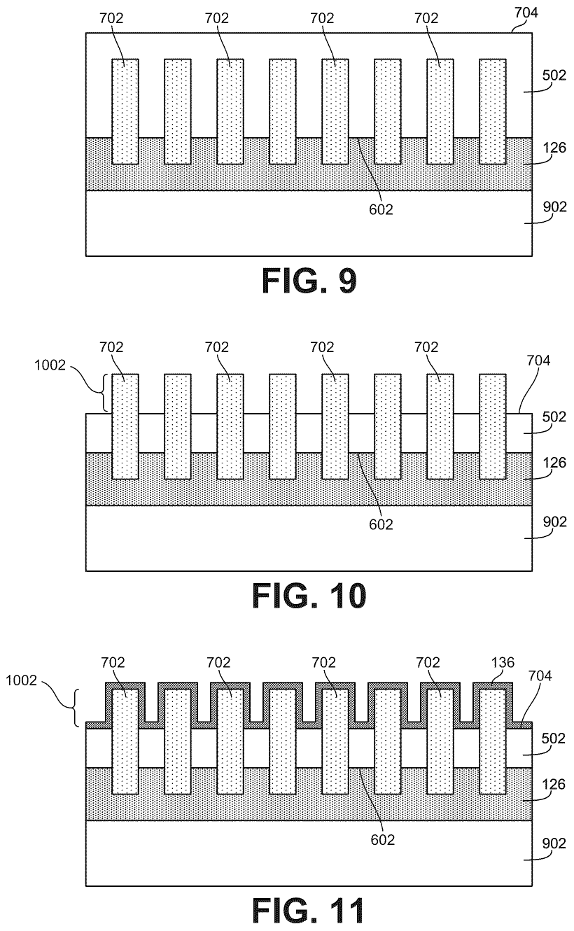

At block 410, the integrated circuit region 126 is attached to a carrier substrate 902 to enable processing of the second side 704 of the substrate 502 as represented in FIG. 9. The carrier substrate 902 is a temporary substrate and, therefore, can be composed of any suitable material (e.g., semiconductor, glass, dielectric, etc.).

At block 412, material of the substrate 502 on the second side 704 is removed (e.g., via etching) to expose portions 1002 of the deep metal vias 702 as represented in FIG. 10. In this example, the exposed portions 1002 correspond to the portion 134 of the pins 118 extending beyond the first surface 120 of the substrate 122 in FIG. 1.

At block 414, the exposed portions 1002 of the deep metal vias 702 are conformally coated with a dielectric material (e.g., the dielectric material 136) as represented in FIG. 11.

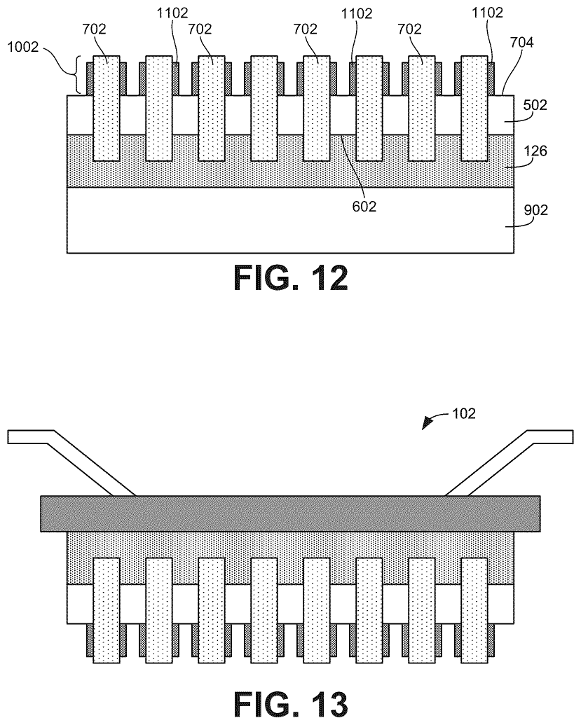

At block 416, the dielectric material 136 is removed from ends of the deep metal vias 702 to define the distal ends or tips 138 of the probe pins 118 as represented in FIG. 12. In some examples, the removal of the dielectric material 136 is accomplished using a directional etching technique so that the dielectric material 136 is retained along the sidewalls of the pins 118 along the exposed portion 1002 extending beyond the second side 704 of the substrate 502. In this manner, the dielectric material 136 is able to provide mechanical support to the pins 118 and also to provide electrical isolation of the pins 118.

At block 418, the fabrication of the probe 102 is completed as represented in FIG. 13. That is, the carrier substrate 1202 is removed and subsequent processing is performed to enable the probe to be electrically and mechanically connected to external components (e.g., the external defect detection controller 128) to enable operation of the probe 102.

FIG. 14 is a block diagram of the defect detection controller 128 of FIG. 1 to control operation of the example probe 102. The defect detection controller 128 of FIG. 14 may be instantiated (e.g., creating an instance of, bring into being for any length of time, materialize, implement, etc.) by processor circuitry such as a central processing unit executing instructions. Additionally or alternatively, defect detection controller 128 of FIG. 14 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 14 may, thus, be instantiated at the same or different times. Some or all of the circuitry may be instantiated, for example, in one or more threads executing concurrently on hardware and/or in series on hardware. Moreover, in some examples, some or all of the circuitry of FIG. 14 may be implemented by microprocessor circuitry executing instructions to implement one or more virtual machines and/or containers.

As shown in the illustrated example, the defect detection controller 128 includes example probe positioning circuitry 1402, example excitation signal generating circuitry 1404, example excitation response analyzing circuitry 1406, example numerical analysis circuitry 1408, example electrical property comparison circuitry 1410, example performance analyzing circuitry 1412, example communications interface circuitry 1414, and example memory 1416.

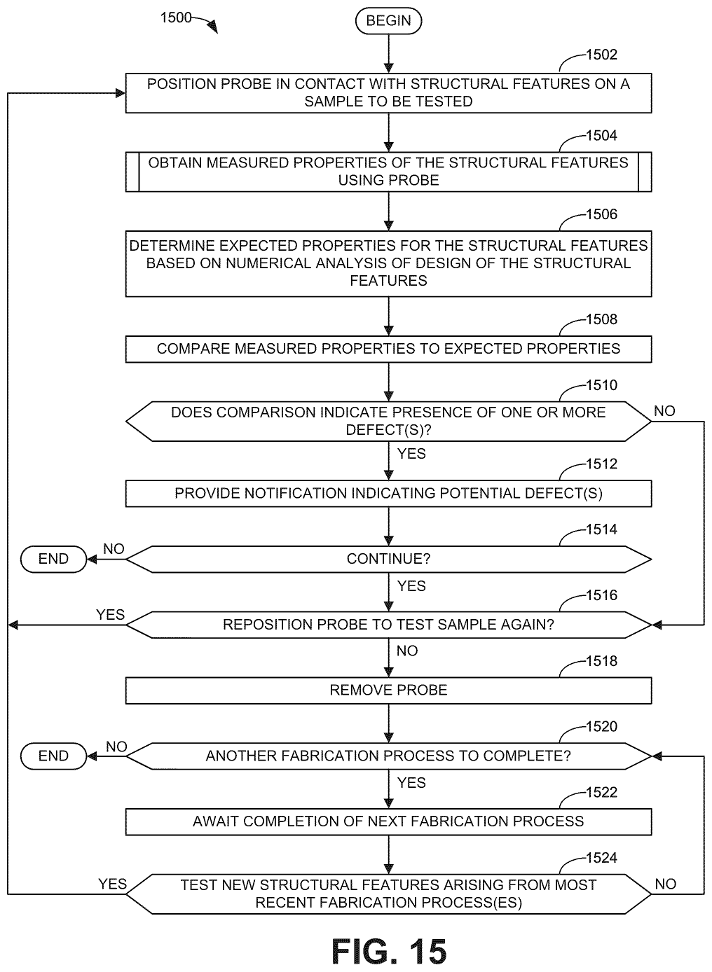

The example probe positioning circuitry 1402 controls and/or determines the position of the probe 102 relative to a sample (e.g., the sample 104) to be measured. Precisely controlling the position of the probe 102 and/or being able to precisely determine the position of the probe 102 enables the precise placement of the boundary conditions (e.g., the location of the excitation signal 140 and the location of the response signal 142). In other words, to properly perform the second numerical analysis 312 described above in connection with FIG. 3, the particular structural features 108 of the sample that each pin 118 is touching needs to be known. As such, the precise position of the probe 102 relative to the sample 104 needs to be known and/or controlled. Precisely positioning the probe 102 with respect to the sample 104 also involves an awareness of the design and/or physical layout of the sample 104. Accordingly, in some examples, the probe positioning circuitry 1402 accesses and/or retrieves a design and/or physical layout of the sample 104 that is stored in the memory 1416. In some examples, the probe positioning circuitry 1402 is instantiated by processor circuitry executing probe positioning instructions and/or configured to perform operations such as those represented by the flowcharts of FIGS. 15-18.

The example excitation signal generating circuitry 1404 generates and/or causes the generation of the excitation signal 140 via one or more of the pins 118. In some examples, if the excitation signal 140 includes multiple signals exciting different ones of the pins 118 in series, the excitation signal generating circuitry 1404 controls the sequence and/or scheduling of such signals. In some examples, the excitation signal generating circuitry 1404 is instantiated by processor circuitry executing excitation signal generating instructions and/or configured to perform operations such as those represented by the flowcharts of FIGS. 15-18.

The example excitation response analyzing circuitry 1406 analyzes the response signal 142 captured by ones of the pins 118 following the application of the excitation signal 140. In some examples, the excitation response analyzing circuitry 1406 causes the response signal 142 and/or results of the analysis of the response signal 142 in the example memory 1416. In some examples, the excitation response analyzing circuitry 1406 is instantiated by processor circuitry executing excitation response analyzing instructions and/or configured to perform operations such as those represented by the flowcharts of FIGS. 15-18.

The example numerical analysis circuitry 1408 serves to analyze the physical layout of the sample 104 (and the associated material properties in the physical layout) using numerical analysis. More particularly, in some examples, the numerical analysis circuitry 1408 implements the first numerical analysis 306 shown and described above in FIG. 3 to determine the target and/or expected electrical properties (e.g., the reference properties 308 of FIG. 3) of individual regions 310 of the sample 104. Further, in some examples, the numerical analysis circuitry 1408 implements the second numerical analysis 312 shown and described above in FIG. 3 to determine the measured electrical properties (e.g., the measured properties 314 of FIG. 3) of individual regions 310 of the sample 104 based on the applied excitation signal 140 and resulting response signal 142 used as boundary conditions for the analysis. In some examples, the numerical analysis circuitry 1408 is instantiated by processor circuitry executing numerical analysis instructions and/or configured to perform operations such as those represented by the flowcharts of FIGS. 15-18.

The example electrical property comparison circuitry 1410 compares the measured properties 314 to the calculated reference properties 308 to identify differences indicative of potential defects in the sample 104. In some examples, electrical property comparison circuitry 1410 calculates a difference between the measured and reference values for individual regions 310. In some such examples, a potential defect is identified when the difference satisfies (e.g., exceeds) a threshold. In some examples, the reference properties 308 correspond to measured properties 314 taken from a different sample 104 (or a different region of the sample) designed with identical structural features 108. In some examples, the electrical property comparison circuitry 1410 is instantiated by processor circuitry executing electrical property comparison instructions and/or configured to perform operations such as those represented by the flowcharts of FIGS. 15-18.

The example performance analyzing circuitry 1412 estimates the performance and/or electrical properties of a semiconductor device (e.g., a semiconductor chip and/or portion thereof) after subsequent fabrication operations based on defects detected in the semiconductor device using the output of the electrical property comparison circuitry 1410. That is, in some examples, the performance analyzing circuitry 1412 takes an output of the electrical property comparison circuitry 1410 at a given point in time during fabrication of a semiconductor device and predicts a final structure for the device based on subsequent processing. Further, in some examples, the performance analyzing circuitry 1412 analyzes the predicted final structure (including any defects detected up to the current point in fabrication) to estimate a performance of the final structure and/or other electrical characteristics of the final structure. In some examples, the performance is calculated based on a numerical analysis of the predicted final structure using the numerical analysis circuitry 1408. In some examples, the performance analyzing circuitry 1412 determines and/or analyzes a predicted intermediate structure that includes structural features yet to be fabricated but does not include all structural features of the final semiconductor device. That is, the performance analyzing circuitry 1412 can estimate the structure and/or associated performance of electrical characteristics at any point in the fabrication process based on measured data collected using the probe 102 at any previous point in the fabrication process. In some examples, the predicted intermediate (or final) structure and/or the results of a numerical analysis of the same are used as the basis to define or calculate reference properties 308 that are to be compared with measured properties 314 once the fabrication process reaches the point in fabrication corresponding to the intermediate (or final) structure. In some examples, the performance analyzing circuitry 1412 is instantiated by processor circuitry executing performance analyzing instructions and/or configured to perform operations such as those represented by the flowcharts of FIGS. 15-18.

The example communications interface circuitry 1414 enables the defect detection controller 128 to interface and/or communicate with external devices. For instance, communications interface circuitry 1414 enables the controller 128 to provide notifications and/or reports to an end user via a user interface and/or any suitable output. Further, in some examples, the communications interface circuitry 1414 enables the end user to provide inputs and/or instructions to direct operation of the defect detection controller 128. In some examples, the communications interface circuitry 1414 is instantiated by processor circuitry executing communications interface instructions and/or configured to perform operations such as those represented by the flowcharts of FIGS. 15-18.

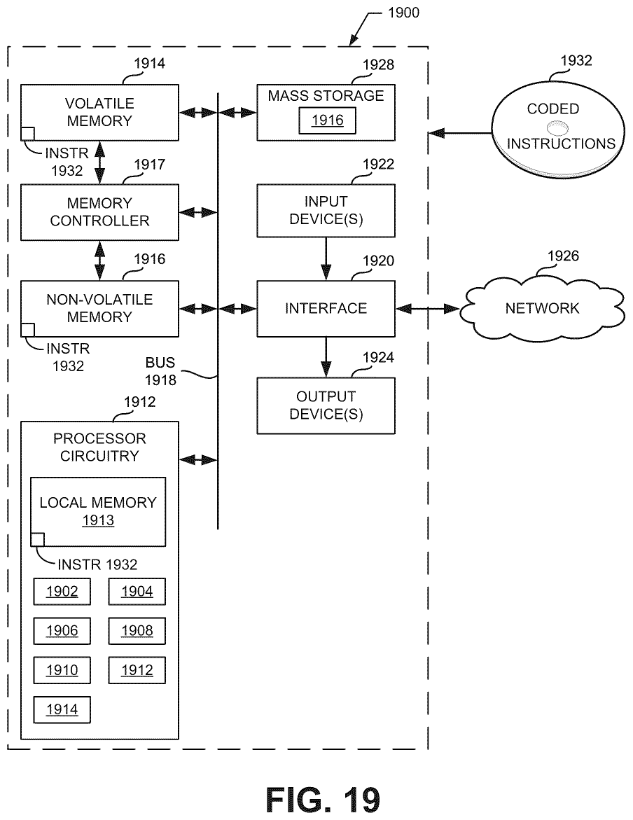

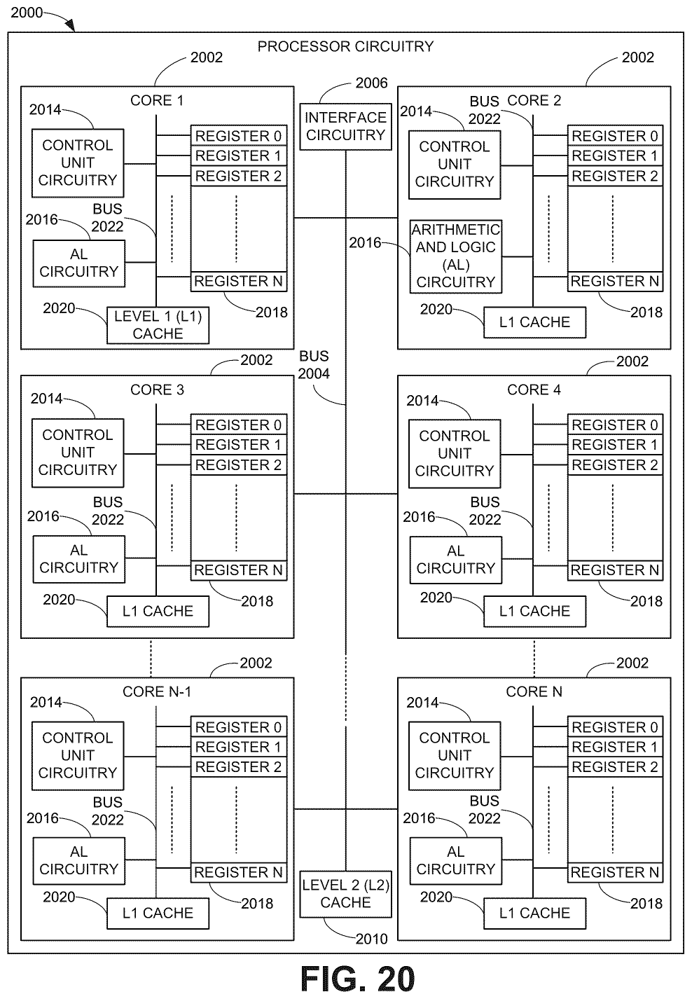

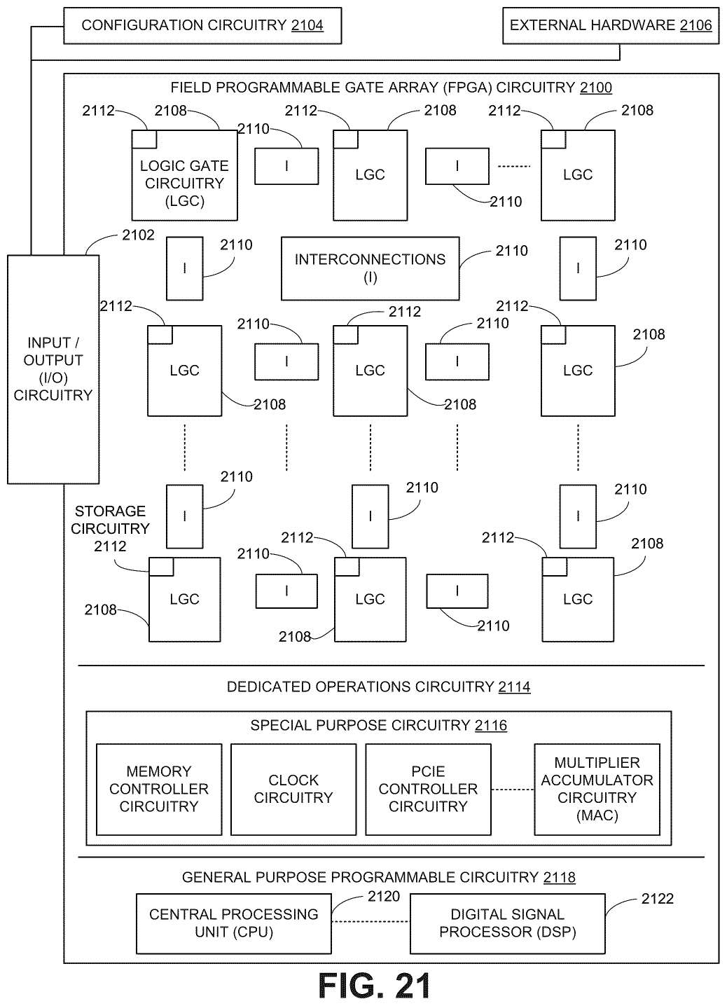

In some examples, the defect detection controller 128 includes means for determining and/or means for controlling a position of the probe 102. For example, the means for determining and/or the means for controlling may be implemented by probe positioning circuitry 1402. In some examples, the probe positioning circuitry 1402 may be instantiated by processor circuitry such as the example processor circuitry 1912 of FIG. 19. For instance, the probe positioning circuitry 1402 may be instantiated by the example microprocessor 2000 of FIG. 20 executing machine executable instructions such as those implemented by at least blocks 1502, 1516, 1518, 1602, 1606, 1702, 1706, 1712 of FIGS. 15-17. In some examples, the probe positioning circuitry 1402 may be instantiated by hardware logic circuitry, which may be implemented by an ASIC, XPU, or the FPGA circuitry 2100 of FIG. 21 structured to perform operations corresponding to the machine readable instructions. Additionally or alternatively, the probe positioning circuitry 1402 may be instantiated by any other combination of hardware, software, and/or firmware. For example, the probe positioning circuitry 1402 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

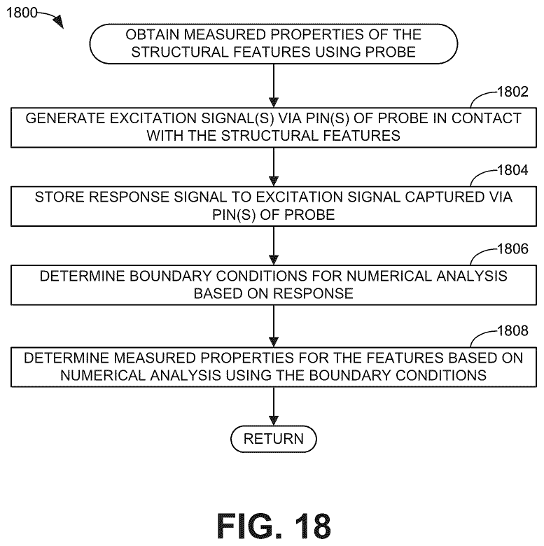

In some examples, the defect detection controller 128 includes means for generating an excitation signal 140. For example, the means for determining may be implemented by excitation signal generating circuitry 1404. In some examples, the excitation signal generating circuitry 1404 may be instantiated by processor circuitry such as the example processor circuitry 1912 of FIG. 19. For instance, the excitation signal generating circuitry 1404 may be instantiated by the example microprocessor 2000 of FIG. 20 executing machine executable instructions such as those implemented by at least blocks 1802 of FIG. 18. In some examples, the excitation signal generating circuitry 1404 may be instantiated by hardware logic circuitry, which may be implemented by an ASIC, XPU, or the FPGA circuitry 2100 of FIG. 21 structured to perform operations corresponding to the machine readable instructions. Additionally or alternatively, the excitation signal generating circuitry 1404 may be instantiated by any other combination of hardware, software, and/or firmware. For example, the excitation signal generating circuitry 1404 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the defect detection controller 128 includes means for generating a response signal, means for determining boundary conditions, and/or means for analyzing a response to the excitation signal. For example, the means for generating, the means for determining, and/or the means for analyzing may be implemented by excitation response analyzing circuitry 1406. In some examples, the excitation response analyzing circuitry 1406 may be instantiated by processor circuitry such as the example processor circuitry 1912 of FIG. 19. For instance, the excitation response analyzing circuitry 1406 may be instantiated by the example microprocessor 2000 of FIG. 20 executing machine executable instructions such as those implemented by at least blocks 1806 of FIG. 18. In some examples, the excitation response analyzing circuitry 1406 may be instantiated by hardware logic circuitry, which may be implemented by an ASIC, XPU, or the FPGA circuitry 2100 of FIG. 21 structured to perform operations corresponding to the machine readable instructions. Additionally or alternatively, the excitation response analyzing circuitry 1406 may be instantiated by any other combination of hardware, software, and/or firmware. For example, the excitation response analyzing circuitry 1406 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the defect detection controller 128 includes means for determining electrical properties of a sample. For example, the means for determining may be implemented by numerical analysis circuitry 1408. In some examples, the numerical analysis circuitry 1408 may be instantiated by processor circuitry such as the example processor circuitry 1912 of FIG. 19. For instance, the numerical analysis circuitry 1408 may be instantiated by the example microprocessor 2000 of FIG. 20 executing machine executable instructions such as those implemented by at least blocks 1506, 1706, 1808 of FIGS. 15, 17, and 18. In some examples, the numerical analysis circuitry 1408 may be instantiated by hardware logic circuitry, which may be implemented by an ASIC, XPU, or the FPGA circuitry 2100 of FIG. 21 structured to perform operations corresponding to the machine readable instructions. Additionally or alternatively, the numerical analysis circuitry 1408 may be instantiated by any other combination of hardware, software, and/or firmware. For example, the numerical analysis circuitry 1408 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the defect detection controller 128 includes means for comparing electrical properties. For example, the means for comparing may be implemented by electrical property comparison circuitry 1410. In some examples, the electrical property comparison circuitry 1410 may be instantiated by processor circuitry such as the example processor circuitry 1912 of FIG. 19. For instance, the electrical property comparison circuitry 1410 may be instantiated by the example microprocessor 2000 of FIG. 20 executing machine executable instructions such as those implemented by at least blocks 1508, 1510, 1610, 1612, 1716, 1718 of FIGS. 15-17. In some examples, the electrical property comparison circuitry 1410 may be instantiated by hardware logic circuitry, which may be implemented by an ASIC, XPU, or the FPGA circuitry 2100 of FIG. 21 structured to perform operations corresponding to the machine readable instructions. Additionally or alternatively, the electrical property comparison circuitry 1410 may be instantiated by any other combination of hardware, software, and/or firmware. For example, the electrical property comparison circuitry 1410 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

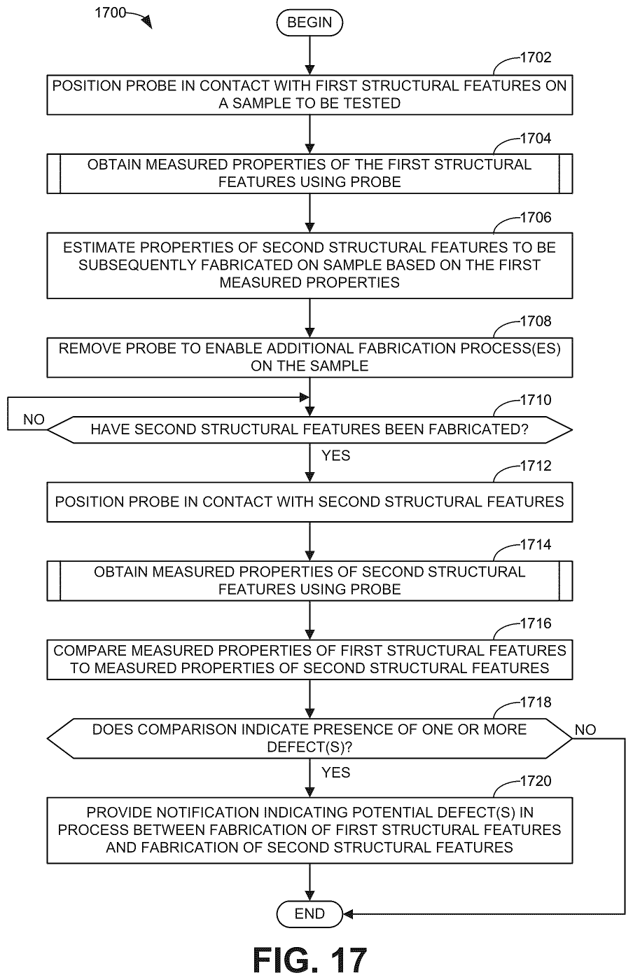

In some examples, the defect detection controller 128 includes means for estimating electrical properties and/or a performance of a semiconductor chip and/or portions thereof. For example, the means for estimating may be implemented by performance analyzing circuitry 1412. In some examples, the performance analyzing circuitry 1412 may be instantiated by processor circuitry such as the example processor circuitry 1912 of FIG. 19. For instance, the performance analyzing circuitry 1412 may be instantiated by the example microprocessor 2000 of FIG. 20 executing machine executable instructions such as those implemented by at least blocks 1706 of FIG. 17. In some examples, the performance analyzing circuitry 1412 may be instantiated by hardware logic circuitry, which may be implemented by an ASIC, XPU, or the FPGA circuitry 2100 of FIG. 21 structured to perform operations corresponding to the machine readable instructions. Additionally or alternatively, the performance analyzing circuitry 1412 may be instantiated by any other combination of hardware, software, and/or firmware. For example, the performance analyzing circuitry 1412 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

In some examples, the defect detection controller 128 includes means for communicating. For example, the means for communicating may be implemented by communications interface circuitry 1414. In some examples, the communications interface circuitry 1414 may be instantiated by processor circuitry such as the example processor circuitry 1912 of FIG. 19. For instance, the communications interface circuitry 1414 may be instantiated by the example microprocessor 2000 of FIG. 20 executing machine executable instructions such as those implemented by at least blocks 1512, 1514, 1614, 1720 of FIGS. 15-17. In some examples, the communications interface circuitry 1414 may be instantiated by hardware logic circuitry, which may be implemented by an ASIC, XPU, or the FPGA circuitry 2100 of FIG. 21 structured to perform operations corresponding to the machine readable instructions. Additionally or alternatively, the communications interface circuitry 1414 may be instantiated by any other combination of hardware, software, and/or firmware. For example, the communications interface circuitry 1414 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

While an example manner of implementing the defect detection controller 128 of FIG. 1 is illustrated in FIG. 14, one or more of the elements, processes, and/or devices illustrated in FIG. 14 may be combined, divided, re-arranged, omitted, eliminated, and/or implemented in any other way. Further, the example probe positioning circuitry 1402, the example excitation signal generating circuitry 1404, the example excitation response analyzing circuitry 1406, the example numerical analysis circuitry 1408, the example electrical property comparison circuitry 1410, the example performance analyzing circuitry 1412, the example communications interface circuitry 1414, the example memory 1416, and/or, more generally, the example defect detection controller 128 of FIG. 1, may be implemented by hardware alone or by hardware in combination with software and/or firmware. Thus, for example, any of the example probe positioning circuitry 1402, the example excitation signal generating circuitry 1404, the example excitation response analyzing circuitry 1406, the example numerical analysis circuitry 1408, the example electrical property comparison circuitry 1410, the example performance analyzing circuitry 1412, the example communications interface circuitry 1414, the example memory 1416, and/or, more generally, the example defect detection controller 128, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example defect detection controller 128 of FIG. 1 may include one or more elements, processes, and/or devices in addition to, or instead of, those illustrated in FIG. 14, and/or may include more than one of any or all of the illustrated elements, processes and devices.

Flowcharts representative of example machine readable instructions, which may be executed to configure processor circuitry to implement the defect detection controller 128 of FIGS. 1 and/or 14, is shown in FIGS. 15-18. The machine readable instructions may be one or more executable programs or portion(s) of an executable program for execution by processor circuitry, such as the processor circuitry 1912 shown in the example processor platform 1900 discussed below in connection with FIG. 19 and/or the example processor circuitry discussed below in connection with FIGS. 20 and/or 21. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowcharts illustrated in FIGS. 15-18, many other methods of implementing the example defect detection controller 128 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 15-18 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 15 is a flowchart representative of example machine readable instructions and/or example operations 1500 that may be executed and/or instantiated by processor circuitry to test or inspect the electrical properties of a sample (e.g., the sample 104) using the probe 102 of FIG. 1. The machine readable instructions and/or the operations 1500 of FIG. 15 begin at block 1502, where the example probe position circuitry 1402 positions the probe 102 in contact with structural features on a sample 104 to be tested. In some examples, the probe 102 may be positioned by an external device and the example probe positioning circuitry 1402 determines the precise position of the probe 102 relative to the sample 104. At block 1504, the defect detection controller 128 obtains measures properties (e.g., measured electrical properties) of the structural features using the probe 102. Further detail regarding the implementation of block 1504 is provided below in connection with FIG. 18.

At block 1506, the example numerical analysis circuitry 1408 determines expected properties for the structural features based on a numerical analysis of a design of the structural features. At block 1508, the example electrical property comparison circuitry 1410 compares the measured properties (obtained at block 1504) to the expected properties (determined at block 1506). At block 1510, the example electrical property comparison circuitry 1410 determines whether the comparison indicates the presence of one or more defect(s). In some examples, the presence of a defect is determined based on a difference between the measured and expected properties satisfying (e.g., exceeding) a threshold). If the comparison indicates defect(s) are present, control advances to block 1512 where the example communications interface circuitry 1414 provides a notification indicating potential defect(s). In some examples, the notification includes information about the nature and/or location of the defect(s) within the sample 104. Thereafter, control advances to block 1514 where the defect detection controller 128 determines whether to continue the process. In some examples, whether to continue after the detection of potential defect(s) may be based on feedback from a user provided via the example communications interface circuitry 1414. If the process is not to continue, the example process of FIG. 15 ends. If the process is to continue, control advances to block 1516. Returning to block 1510, if the comparison does not indicate the presence of defect(s), control advances directly to block 1516.

At block 1516, the example probe positioning circuitry 1402 determines whether to reposition the probe 102 to test the sample again. In some examples, a new test at a new location is performed if the entire area covered by the probe 102 is less than the entire area of the sample 104. For instance, if the sample 104 corresponds to a semiconductor wafer with multiple dies and the probe 102 is dimensioned to test one die at a time, the example probe positioning circuitry 1402 may determine to reposition the probe 102 to test a different die. Additionally or alternatively, in some examples, the example probe positioning circuitry 1402 may determine to test the same structural features (e.g., the same area) of the sample except with the probe 102 slightly shifted to increase the resolution of the results. For instance, assume the that pins 118 of the probe are separated by a pitch of 100 nm. In some examples, the example probe positioning circuitry 1402 may determine to reposition the probe 102 by shifting it by 50 nm (e.g., shifting the probe by less than a pitch of the pins 118) such that the pins 118 will contact the sample 104 at locations that were between the pins 118 during the previous test. In this manner, the resolution of measurement data can be even higher than the spatial density of the pins 118. In some examples, multiple tests with the probe slightly shifted each time are performed and the results of the different tests are combined or aggregated into the measured properties before being compared to the expected properties (at block 1508). In view of the foregoing, if the probe positioning circuitry 1402 determines to reposition the probe 102, control returns to block 1502. Otherwise, control advances to block 1518.

If the example probe positioning circuitry 1402 determines not to reposition the probe 102, control advances to block 1518 where the example probe positioning circuitry 1402 removes the probe 102 from the sample 104. In some examples, the probe 102 is removed to enable additional fabrication processes to be performed to further develop the sample 104. In some examples, a cleaning process may immediately follow the removal of the probe 102 to remove potential contamination on the sample 104 arising from the probe 102 being in contact with the sample 104. At block 1520, the defect detection controller 128 determines whether there is an additional fabrication process to be completed. If there are additional fabrication processes to be completed, control advances to block 1522 to await completion of the next fabrication process. Thereafter, at block 1524, the defect detection controller 128 determines whether to test new structural features arising from the most recent fabrication process(es). That is, it is possible for the probe 102 to test the sample 104 between every fabrication process. However, in some examples, multiple fabrication processes may be performed between successive tests of the sample 104. Thus, if a new test is to be performed, control returns to block 1502 to repeat the process. If no new test is to be performed, control returns to block 1520 to determine whether there is another fabrication process to be completed. If there are no additional fabrication processes, then the fabrication process is complete and the example process of FIG. 15 ends.

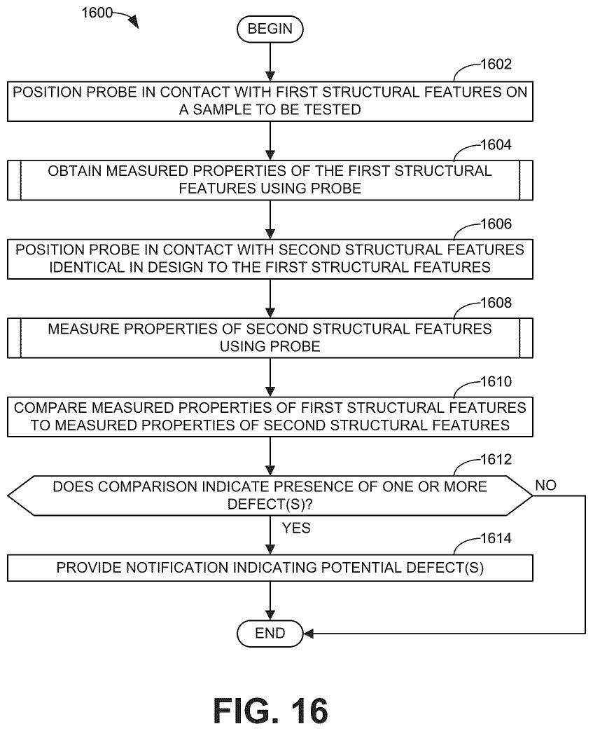

FIG. 16 is a flowchart representative of example machine readable instructions and/or example operations 1600 that may be executed and/or instantiated by processor circuitry to test or inspect the electrical properties of a sample (e.g., the sample 104) using the probe 102 of FIG. 1. The machine readable instructions and/or the operations 1600 of FIG. 16 begin at block 1602, where the example probe position circuitry 1402 positions the probe 102 in contact with first structural features on a sample 104 to be tested. At block 1604, the defect detection controller 128 obtains measured properties (e.g., measured electrical properties) of the first structural features using the probe 102. In some examples, blocks 1602 and 1604 are implemented in substantially the same way as blocks 1502 and 1504 of FIG. 15. Thus, as with block 1504, further detail regarding the implementation of block 1604 is provided below in connection with FIG. 18.

At block 1606, the example probe position circuitry 1402 positions the probe 102 in contact with second structural features identical in design to the first structural features. In some examples, the second structural features are part of the same sample 104 (e.g., the same semiconductor wafer) as the first structural features but correspond to a different portion or area (e.g., a different die) of the sample 104. In some examples, the second structural features are associated with a different sample (e.g., a different semiconductor wafer). At block 1608, the defect detection controller 128 obtains measured properties of the second structural features using the probe 102. In some examples, the implementation of block 1606 is substantially the same as the implementation of block 1604. Thus, as with block 1604, further detail regarding the implementation of block 1608 is provided below in connection with FIG. 18. In some examples, where the second structural features correspond to a different sample than the sample containing the first structural features, blocks 1606 and 1608 can be performed independent of (e.g., parallel to) blocks 1602 and 1604. Thus, in some examples, the first and second structural features can be tested at disparate points in time.

At block 1610, the example electrical property comparison circuitry 1410 compares the measured properties of the first structural features (obtained at block 1604) to the measured properties of the second structural features (obtained at block 1608). At block 1612, the example electrical property comparison circuitry 1410 determines whether the comparison indicates the presence of one or more defect(s). If the comparison indicates defect(s) are present, control advances to block 1614 where the example communications interface circuitry 1414 provides a notification indicating potential defect(s). Thereafter, the example process of FIG. 16 ends. If no defects are detected (as determined at block 1612), then the example process of FIG. 16 ends.

FIG. 17 is a flowchart representative of example machine readable instructions and/or example operations 1700 that may be executed and/or instantiated by processor circuitry to test or inspect the electrical properties of a sample (e.g., the sample 104) using the probe 102 of FIG. 1. The machine readable instructions and/or the operations 1700 of FIG. 17 begin at block 1702, where the example probe position circuitry 1402 positions the probe 102 in contact with first structural features on a sample 104 to be tested. At block 1704, the defect detection controller 128 obtains measured properties (e.g., measured electrical properties) of the first structural features using the probe 102. In some examples, blocks 1702 and 1704 are implemented in substantially the same way as blocks 1502 and 1504 of FIG. 15. Thus, as with block 1504, further detail regarding the implementation of block 1704 is provided below in connection with FIG. 18.

At block 1706, the example performance analyzing circuitry 1412 and/or the numerical analysis circuitry 1408 estimates properties of second structural features to be subsequently fabricated on the sample based on the first measured properties. At block 1706, the example probe positioning circuitry 1402 removes the probe 102 to enable additional fabrication processes on the sample 104. At block 1710, the defect detection controller 128 determines whether the second structural features have been fabricated. If not, control remains at block 1710. If so, control advances to block 1712 where the example probe position circuitry 1402 positions the probe 102 in contact with second structural features. At block 1714, the defect detection controller 128 obtains measured properties of the second structural features using the probe 102. In some examples, the implementation of block 1714 is substantially the same as the implementation of block 1704. Thus, as with block 1704, further detail regarding the implementation of block 1714 is provided below in connection with FIG. 18.

At block 1716, the example electrical property comparison circuitry 1410 compares the measured properties of the first structural features (obtained at block 1704) to the measured properties of the second structural features (obtained at block 1714). At block 1718, the example electrical property comparison circuitry 1410 determines whether the comparison indicates the presence of one or more defect(s). If the comparison indicates defect(s) are present, control advances to block 1720 where the example communications interface circuitry 1414 provides a notification indicating potential defect(s) in the process between fabrication of the first structural features and the fabrication of the second structural features. Thereafter, the example process of FIG. 17 ends. If no defects are detected (as determined at block 1718), then the example process of FIG. 17 ends.

FIG. 18 is a flowchart representative of example machine readable instructions and/or example operations 1800 that may be executed and/or instantiated by processor circuitry to implement any one of blocks 1504, 1604, 1608, 1704, 1714 of FIGS. 15-17. The machine readable instructions and/or the operations 1800 of FIG. 18 begin at block 1802, where the example excitation signal generating circuitry 1404 generates excitation signal(s) (e.g., the excitation signal 140 of FIG. 1) via pin(s) of probe in contact with the structural features. At block 1804, the example memory 1416 stores a response signal (e.g., the response signal 142 of FIG. 1) to the excitation signal. At block 1806, the excitation response analyzing circuitry 1406 determines boundary conditions for a numerical analysis based on the response signal. At block 1808, the example numerical analysis circuitry 1408 determines the measured properties for the structural features based on a numerical analysis of the structural features using the boundary conditions. Thereafter, the example process of FIG. 18 ends and returns to complete the process of any one of FIGS. 15, 16, and/or 17.

FIG. 19 is a block diagram of an example processor platform 1900 structured to execute and/or instantiate the machine readable instructions and/or the operations of FIGS. 15-18 to implement the defect detection controller 128 of FIGS. 1 and/or 14. The processor platform 1900 can be, for example, a server, a personal computer, a workstation, a self-learning machine (e.g., a neural network), or any other type of computing device.

The processor platform 1900 of the illustrated example includes processor circuitry 1912. The processor circuitry 1912 of the illustrated example is hardware. For example, the processor circuitry 1912 can be implemented by one or more integrated circuits, logic circuits, FPGAs, microprocessors, CPUs, GPUs, DSPs, and/or microcontrollers from any desired family or manufacturer. The processor circuitry 1912 may be implemented by one or more semiconductor based (e.g., silicon based) devices. In this example, the processor circuitry 1912 implements the example probe positioning circuitry 1402, the example excitation signal generating circuitry 1404, the example excitation response analyzing circuitry 1406, the example numerical analysis circuitry 1408, the example electrical property comparison circuitry 1410, the example performance analyzing circuitry 1412, and the example communications interface circuitry 1414.

The processor circuitry 1912 of the illustrated example includes a local memory 1913 (e.g., a cache, registers, etc.). The processor circuitry 1912 of the illustrated example is in communication with a main memory including a volatile memory 1914 and a non-volatile memory 1916 by a bus 1918. The volatile memory 1914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1916 may be implemented by flash memory and/or any other desired type of memory device. Access to the main memory 1914, 1916 of the illustrated example is controlled by a memory controller 1917.

The processor platform 1900 of the illustrated example also includes interface circuitry 1920. The interface circuitry 1920 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1922 are connected to the interface circuitry 1920. The input device(s) 1922 permit(s) a user to enter data and/or commands into the processor circuitry 1912. The input device(s) 1922 can be implemented by, for example, an audio sensor, a microphone, a camera (still or video), a keyboard, a button, a mouse, a touchscreen, a track-pad, a trackball, an isopoint device, and/or a voice recognition system.

One or more output devices 1924 are also connected to the interface circuitry 1920 of the illustrated example. The output device(s) 1924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1920 of the illustrated example, thus, typically includes a graphics driver card, a graphics driver chip, and/or graphics processor circuitry such as a GPU.

The interface circuitry 1920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1926. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 1900 of the illustrated example also includes one or more mass storage devices 1928 to store software and/or data. Examples of such mass storage devices 1928 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine readable instructions 1932, which may be implemented by the machine readable instructions of FIGS. 15-18, may be stored in the mass storage device 1928, in the volatile memory 1914, in the non-volatile memory 1916, and/or on a removable non-transitory computer readable storage medium such as a CD or DVD.

FIG. 20 is a block diagram of an example implementation of the processor circuitry 1912 of FIG. 19. In this example, the processor circuitry 1912 of FIG. 19 is implemented by a microprocessor 2000. For example, the microprocessor 2000 may be a general purpose microprocessor (e.g., general purpose microprocessor circuitry). The microprocessor 2000 executes some or all of the machine readable instructions of the flowcharts of FIGS. 15-18 to effectively instantiate the circuitry of FIG. 14 as logic circuits to perform the operations corresponding to those machine readable instructions. In some such examples, the circuitry of FIG. 14 is instantiated by the hardware circuits of the microprocessor 2000 in combination with the instructions. For example, the microprocessor 2000 may be implemented by multi-core hardware circuitry such as a CPU, a DSP, a GPU, an XPU, etc. Although it may include any number of example cores 2002 (e.g., 1 core), the microprocessor 2000 of this example is a multi-core semiconductor device including N cores. The cores 2002 of the microprocessor 2000 may operate independently or may cooperate to execute machine readable instructions. For example, machine code corresponding to a firmware program, an embedded software program, or a software program may be executed by one of the cores 2002 or may be executed by multiple ones of the cores 2002 at the same or different times. In some examples, the machine code corresponding to the firmware program, the embedded software program, or the software program is split into threads and executed in parallel by two or more of the cores 2002. The software program may correspond to a portion or all of the machine readable instructions and/or operations represented by the flowcharts of FIGS. 15-18.

The cores 2002 may communicate by a first example bus 2004. In some examples, the first bus 2004 may be implemented by a communication bus to effectuate communication associated with one(s) of the cores 2002. For example, the first bus 2004 may be implemented by at least one of an Inter-Integrated Circuit (I2C) bus, a Serial Peripheral Interface (SPI) bus, a PCI bus, or a PCIe bus. Additionally or alternatively, the first bus 2004 may be implemented by any other type of computing or electrical bus. The cores 2002 may obtain data, instructions, and/or signals from one or more external devices by example interface circuitry 2006. The cores 2002 may output data, instructions, and/or signals to the one or more external devices by the interface circuitry 2006. Although the cores 2002 of this example include example local memory 2020 (e.g., Level 1 (L1) cache that may be split into an L1 data cache and an L1 instruction cache), the microprocessor 2000 also includes example shared memory 2010 that may be shared by the cores (e.g., Level 2 (L2 cache)) for high-speed access to data and/or instructions. Data and/or instructions may be transferred (e.g., shared) by writing to and/or reading from the shared memory 2010. The local memory 2020 of each of the cores 2002 and the shared memory 2010 may be part of a hierarchy of storage devices including multiple levels of cache memory and the main memory (e.g., the main memory 1914, 1916 of FIG. 19). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2002 may be referred to as a CPU, DSP, GPU, etc., or any other type of hardware circuitry. Each core 2002 includes control unit circuitry 2014, arithmetic and logic (AL) circuitry (sometimes referred to as an ALU) 2016, a plurality of registers 2018, the local memory 2020, and a second example bus 2022. Other structures may be present. For example, each core 2002 may include vector unit circuitry, single instruction multiple data (SIMD) unit circuitry, load/store unit (LSU) circuitry, branch/jump unit circuitry, floating-point unit (FPU) circuitry, etc. The control unit circuitry 2014 includes semiconductor-based circuits structured to control (e.g., coordinate) data movement within the corresponding core 2002. The AL circuitry 2016 includes semiconductor-based circuits structured to perform one or more mathematic and/or logic operations on the data within the corresponding core 2002. The AL circuitry 2016 of some examples performs integer based operations. In other examples, the AL circuitry 2016 also performs floating point operations. In yet other examples, the AL circuitry 2016 may include first AL circuitry that performs integer based operations and second AL circuitry that performs floating point operations. In some examples, the AL circuitry 2016 may be referred to as an Arithmetic Logic Unit (ALU). The registers 2018 are semiconductor-based structures to store data and/or instructions such as results of one or more of the operations performed by the AL circuitry 2016 of the corresponding core 2002. For example, the registers 2018 may include vector register(s), SIMD register(s), general purpose register(s), flag register(s), segment register(s), machine specific register(s), instruction pointer register(s), control register(s), debug register(s), memory management register(s), machine check register(s), etc. The registers 2018 may be arranged in a bank as shown in FIG. 20. Alternatively, the registers 2018 may be organized in any other arrangement, format, or structure including distributed throughout the core 2002 to shorten access time. The second bus 2022 may be implemented by at least one of an I2C bus, a SPI bus, a PCI bus, or a PCIe bus

Each core 2002 and/or, more generally, the microprocessor 2000 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2000 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 21 is a block diagram of another example implementation of the processor circuitry 1912 of FIG. 19. In this example, the processor circuitry 1912 is implemented by FPGA circuitry 2100. For example, the FPGA circuitry 2100 may be implemented by an FPGA. The FPGA circuitry 2100 can be used, for example, to perform operations that could otherwise be performed by the example microprocessor 2000 of FIG. 20 executing corresponding machine readable instructions. However, once configured, the FPGA circuitry 2100 instantiates the machine readable instructions in hardware and, thus, can often execute the operations faster than they could be performed by a general purpose microprocessor executing the corresponding software.

More specifically, in contrast to the microprocessor 2000 of FIG. 20 described above (which is a general purpose device that may be programmed to execute some or all of the machine readable instructions represented by the flowcharts of FIG. 15-18 but whose interconnections and logic circuitry are fixed once fabricated), the FPGA circuitry 2100 of the example of FIG. 21 includes interconnections and logic circuitry that may be configured and/or interconnected in different ways after fabrication to instantiate, for example, some or all of the machine readable instructions represented by the flowcharts of FIG. 15-18. In particular, the FPGA circuitry 2100 may be thought of as an array of logic gates, interconnections, and switches. The switches can be programmed to change how the logic gates are interconnected by the interconnections, effectively forming one or more dedicated logic circuits (unless and until the FPGA circuitry 2100 is reprogrammed). The configured logic circuits enable the logic gates to cooperate in different ways to perform different operations on data received by input circuitry. Those operations may correspond to some or all of the software represented by the flowcharts of FIG. 15-18. As such, the FPGA circuitry 2100 may be structured to effectively instantiate some or all of the machine readable instructions of the flowcharts of FIG. 15-18 as dedicated logic circuits to perform the operations corresponding to those software instructions in a dedicated manner analogous to an ASIC. Therefore, the FPGA circuitry 2100 may perform the operations corresponding to the some or all of the machine readable instructions of FIGS. 15-18 faster than the general purpose microprocessor can execute the same.

In the example of FIG. 21, the FPGA circuitry 2100 is structured to be programmed (and/or reprogrammed one or more times) by an end user by a hardware description language (HDL) such as Verilog. The FPGA circuitry 2100 of FIG. 21, includes example input/output (I/O) circuitry 2102 to obtain and/or output data to/from example configuration circuitry 2104 and/or external hardware 2106. For example, the configuration circuitry 2104 may be implemented by interface circuitry that may obtain machine readable instructions to configure the FPGA circuitry 2100, or portion(s) thereof. In some such examples, the configuration circuitry 2104 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 2106 may be implemented by external hardware circuitry. For example, the external hardware 2106 may be implemented by the microprocessor 2000 of FIG. 20. The FPGA circuitry 2100 also includes an array of example logic gate circuitry 2108, a plurality of example configurable interconnections 2110, and example storage circuitry 2112. The logic gate circuitry 2108 and the configurable interconnections 2110 are configurable to instantiate one or more operations that may correspond to at least some of the machine readable instructions of FIGS. 15-18 and/or other desired operations. The logic gate circuitry 2108 shown in FIG. 21 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2108 to enable configuration of the electrical structures and/or the logic gates to form circuits to perform desired operations. The logic gate circuitry 2108 may include other electrical structures such as look-up tables (LUTs), registers (e.g., flip-flops or latches), multiplexers, etc.

The configurable interconnections 2110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2108 to program desired logic circuits.

The storage circuitry 2112 of the illustrated example is structured to store result(s) of the one or more of the operations performed by corresponding logic gates. The storage circuitry 2112 may be implemented by registers or the like. In the illustrated example, the storage circuitry 2112 is distributed amongst the logic gate circuitry 2108 to facilitate access and increase execution speed.

The example FPGA circuitry 2100 of FIG. 21 also includes example Dedicated Operations Circuitry 2114. In this example, the Dedicated Operations Circuitry 2114 includes special purpose circuitry 2116 that may be invoked to implement commonly used functions to avoid the need to program those functions in the field. Examples of such special purpose circuitry 2116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2100 may also include example general purpose programmable circuitry 2118 such as an example CPU 2120 and/or an example DSP 2122. Other general purpose programmable circuitry 2118 may additionally or alternatively be present such as a GPU, an XPU, etc., that can be programmed to perform other operations.

Although FIGS. 20 and 21 illustrate two example implementations of the processor circuitry 1912 of FIG. 19, many other approaches are contemplated. For example, as mentioned above, modern FPGA circuitry may include an on-board CPU, such as one or more of the example CPU 2120 of FIG. 21. Therefore, the processor circuitry 1912 of FIG. 19 may additionally be implemented by combining the example microprocessor 2000 of FIG. 20 and the example FPGA circuitry 2100 of FIG. 21. In some such hybrid examples, a first portion of the machine readable instructions represented by the flowcharts of FIG. 15-18 may be executed by one or more of the cores 2002 of FIG. 20, a second portion of the machine readable instructions represented by the flowcharts of FIG. 15-18 may be executed by the FPGA circuitry 2100 of FIG. 21, and/or a third portion of the machine readable instructions represented by the flowcharts of FIG. 15-18 may be executed by an ASIC. It should be understood that some or all of the circuitry of FIG. 14 may, thus, be instantiated at the same or different times. Some or all of the circuitry may be instantiated, for example, in one or more threads executing concurrently and/or in series. Moreover, in some examples, some or all of the circuitry of FIG. 14 may be implemented within one or more virtual machines and/or containers executing on the microprocessor.

In some examples, the processor circuitry 1912 of FIG. 19 may be in one or more packages. For example, the microprocessor 2000 of FIG. 20 and/or the FPGA circuitry 2100 of FIG. 21 may be in one or more packages. In some examples, an XPU may be implemented by the processor circuitry 1912 of FIG. 19, which may be in one or more packages. For example, the XPU may include a CPU in one package, a DSP in another package, a GPU in yet another package, and an FPGA in still yet another package.

From the foregoing, it will be appreciated that example systems, methods, apparatus, and articles of manufacture have been disclosed that enable the measurement or testing of the electrical properties of structural features fabricated on a semiconductor chip at any point during the fabrication process (e.g., during FEOL processing and/or during BEOL processing). Further, disclosed examples also enable the measurement or testing of electrical properties after fabrication is complete to debug a semiconductor chip. The testing or measurement is accomplished through a probe include a large array of relatively small and densely arranged pins that can be positioned in contact with specific structural features on the semiconductor chip being fabricated and excited by an excitation signal to then capture a resulting response signal. The excitation signal can be applied to any structural features having any shape and made of any materials and, therefore, is not limited to traditional electrical testing that requires completed electrical circuits and/or that requires pins to be positioned or landed on specifically located contact pads. The results of such testing can be compared against expected values for the electrical properties of the structural features being measured to identify potential defects in the semiconductor chip. Because examples disclosed herein can be performed at any time during the fabrication process, it is possible to detect defect much sooner than would otherwise be possible using other existing defect detection techniques. Disclosed systems, methods, apparatus, and articles of manufacture are accordingly directed to one or more improvement(s) in the operation of a machine such as a computer or other electronic and/or mechanical device.

Further examples and combinations thereof include the following:

Example 1 includes an apparatus comprising a substrate, integrated circuitry on a first side of the substrate, and an array of pins extending through the substrate, the pins including first ends on the first side of the substrate and second ends protruding beyond a second side of the substrate opposite the first side.

Example 2 includes the apparatus of example 1, wherein the integrated circuitry includes an application-specific integrated circuit (ASIC) with active semiconductor components.

Example 3 includes the apparatus of any one of examples 1 or 2, wherein the integrated circuitry includes passive circuitry to enable electrical coupling of the array of pins to external processor circuitry.

Example 4 includes the apparatus of any one of examples 1-3, wherein the second ends of the pins are exposed to enable the pins to contact structural features of semiconductor components fabricated on a semiconductor wafer, the semiconductor wafer distinct from the substrate.

Example 5 includes the apparatus of example 4, wherein the semiconductor components correspond to transistors not yet completely fabricated on the semiconductor wafer.

Example 6 includes the apparatus of any one of examples 4 or 5, wherein portions of the pins extending between the second side of the substrate and the exposed second ends are covered by a dielectric material.

Example 7 includes the apparatus of any one of examples 4-6, wherein first ones of the pins are to provide an excitation signal to the structural features and second ones of the pins are to capture a response signal based on a path of the excitation signal through the structural features.

Example 8 includes the apparatus of any one of examples 4-7, wherein the pins are distributed across a first area, the semiconductor wafer including regions corresponding to a plurality of semiconductor chips, a first one of the semiconductor chips corresponding to a second area of the semiconductor wafer, a size of the first area approximately equal to or greater than the second area.

Example 9 includes the apparatus of any one of examples 1-8, wherein adjacent ones of the pins are spaced less than 1 um apart.

Example 10 includes the apparatus of any one of examples 1-9, wherein the array of pins includes more than 100,000 pins.

Example 11 includes the apparatus of any one of examples 1-10, wherein the pins include cobalt.

Example 12 includes the apparatus of any one of examples 1-11, wherein the substrate is a semiconductor substrate.

Example 13 includes the apparatus of any one of examples 1-11, wherein the substrate is a dielectric substrate.

Example 14 includes a method of manufacturing a probe to measure electrical properties of structural features on a semiconductor wafer, the method comprising fabricating circuitry on a first side of a substrate, the substrate different than the semiconductor wafer, providing an array of metal vias extending through the substrate toward a second side of the substrate opposite the first side, and removing a portion of the substrate to expose ends of the metal vias.

Example 15 includes the method of example 14, further including depositing a dielectric material on to sidewalls of the exposed ends of the metal vias.

Example 16 includes the method of any one of examples 14 or 15, wherein fabricating the circuitry includes fabricating an application-specific integrated circuit (ASIC) with active semiconductor components.

Example 17 includes the method of any one of examples 14-16, wherein a width of ones of the metal vias is less than 150 nm.

Example 18 includes an apparatus comprising at least one memory, machine readable instructions, and processor circuitry to at least one of instantiate or execute the machine readable instructions to position an array of pins of a probe in contact with structural features fabricated on a semiconductor wafer, cause a first set of the pins to deliver an excitation signal to the structural features, capture, via a second set of the pins, a response signal based on a path of the excitation signal through the structural features, determine measured properties of the structural features based on the response signal, and identify a location of a potential defect in the structural features based on the measured properties.

Example 19 includes the apparatus of example 16, wherein the processor circuitry is to compare the measured properties to reference properties for the structural features, and identify the location of the potential defect based on the comparison.

Example 20 includes the apparatus of example 18, wherein the structural features are first structural features, and the reference properties are based on separate measurements of second structural features distinct and separate from the first structural features, the second structural features having a same design as the first structural features.

Example 21 includes the apparatus of any one of examples 19 or 20, wherein the processor circuitry is to calculate the reference properties based on a numerical analysis of a design of the structural features.

Example 22 includes the apparatus of any one of examples 18-21, wherein the processor circuitry is to determine the measured properties based on a numerical analysis of a design of the structural features, the response signal defining a boundary condition for the numerical analysis.

Example 23 includes the apparatus of any one of examples 18-22, wherein the processor circuitry is to generate a notification indicating the potential defect.

Example 24 includes the apparatus of any one of examples 18-23, wherein the processor circuitry is to cause a first subset of the first set of pins to deliver a first portion of the excitation signal to the structural features at a first point in time, and cause a second subset of the first set of pins to deliver a second portion of the excitation signal to the structural features at a second point in time after the first point in time.

Example 25 includes the apparatus of any one of examples 18-24, wherein the structural features correspond to parts of transistors, the processor circuitry to position the array of pins of the probe in contact with the structural features prior to completion of fabrication of the transistors.

Example 26 includes the apparatus of any one of examples 18-25, wherein the structural features are first structural features, the excitation signal is a first excitation signal, the response signal is a first response signal, and the measured properties are first measured properties, the processor circuitry to estimate second measured properties for second structural features based on the first measured properties, the second structural features fabricated on the semiconductor wafer after fabrication of the first structural features, capture a second response signal based on a second excitation signal applied to the second structural features, determine the second measured properties of the structural features based on the second response signal, and compare the second measured properties to the estimation of the second measured properties.

Example 27 includes a non-transitory machine readable storage medium comprising instructions that, when executed, cause processor circuitry to at least position an array of pins of a probe in contact with structural features fabricated on a semiconductor wafer, cause a first set of the pins to deliver an excitation signal to the structural features, capture, via a second set of the pins, a response signal based on a path of the excitation signal through the structural features, determine measured properties of the structural features based on the response signal, and identify a location of a potential defect in the structural features based on the measured properties.

Example 28 includes the machine readable storage medium of example 27, wherein the instructions cause the processor circuitry to compare the measured properties to reference properties for the structural features, and identify the location of the potential defect based on the comparison.

Example 29 includes the machine readable storage medium of example 28, wherein the structural features are first structural features, and the reference properties are based on separate measurements of second structural features distinct and separate from the first structural features, the second structural features having a same design as the first structural features.

Example 30 includes the machine readable storage medium of any one of examples 28 or 29, wherein the instructions cause the processor circuitry to calculate the reference properties based on a numerical analysis of a design of the structural features.

Example 31 includes the machine readable storage medium of any one of examples 27-30, wherein the instructions cause the processor circuitry to determine the measured properties based on a numerical analysis of a design of the structural features, the response signal defining a boundary condition for the numerical analysis.

Example 32 includes the machine readable storage medium of any one of examples 27-31, wherein the instructions cause the processor circuitry to generate a notification indicating the potential defect.

Example 33 includes the machine readable storage medium of any one of examples 27-32, wherein the instructions cause the processor circuitry to cause a first subset of the first set of pins to deliver a first portion of the excitation signal to the structural features at a first point in time, and cause a second subset of the first set of pins to deliver a second portion of the excitation signal to the structural features at a second point in time after the first point in time.

Example 34 includes the machine readable storage medium of any one of examples 27-33, wherein the structural features correspond to parts of transistors, the instructions to cause the processor circuitry to position the array of pins of the probe in contact with the structural features prior to completion of fabrication of the transistors.

Example 35 includes the machine readable storage medium of any one of examples 27-34, wherein the structural features are first structural features, the excitation signal is a first excitation signal, the response signal is a first response signal, and the measured properties are first measured properties, the instructions to cause the processor circuitry to estimate second measured properties for second structural features based on the first measured properties, the second structural features fabricated on the semiconductor wafer after fabrication of the first structural features, capture a second response signal based on a second excitation signal applied to the second structural features, determine the second measured properties of the structural features based on the second response signal, and compare the second measured properties to the estimation of the second measured properties.

Example 36 includes a method comprising positioning an array of pins of a probe in contact with structural features fabricated on a semiconductor wafer, causing a first set of the pins to deliver an excitation signal to the structural features, capturing, via a second set of the pins, a response signal based on a path of the excitation signal through the structural features, determining, by executing an instruction with processor circuitry, measured properties of the structural features based on the response signal, and identifying, by executing an instruction with the processor circuitry, a location of a potential defect in the structural features based on the measured properties.

Example 37 includes the method of example 36, further including comparing the measured properties to reference properties for the structural features, and identifying the location of the potential defect based on the comparison.

Example 38 includes the method of example 37, wherein the structural features are first structural features, and the reference properties are based on separate measurements of second structural features distinct and separate from the first structural features, the second structural features having a same design as the first structural features.

Example 39 includes the method of any one of examples 37 or 37, further including calculating the reference properties based on a numerical analysis of a design of the structural features.

Example 40 includes the method of any one of examples 36-39, further including determining the measured properties based on a numerical analysis of a design of the structural features, the response signal defining a boundary condition for the numerical analysis.

Example 41 includes the method of any one of examples 36-40, further including providing a notification indicating the potential defect.

Example 42 includes the method of any one of examples 36-41, further including causing a first subset of the first set of pins to deliver a first portion of the excitation signal to the structural features at a first point in time, and causing a second subset of the first set of pins to deliver a second portion of the excitation signal to the structural features at a second point in time after the first point in time.

Example 43 includes the method of any one of examples 36-42, wherein the structural features correspond to parts of transistors, the method further including positioning the array of pins of the probe in contact with the structural features prior to completion of fabrication of the transistors.

Example 44 includes the method of any one of examples 36-43, wherein the structural features are first structural features, the excitation signal is a first excitation signal, the response signal is a first response signal, and the measured properties are first measured properties, the method further including estimating second measured properties for second structural features based on the first measured properties, the second structural features fabricated on the semiconductor wafer after fabrication of the first structural features, capturing a second response signal based on a second excitation signal applied to the second structural features, determining the second measured properties of the structural features based on the second response signal, and comparing the second measured properties to the estimation of the second measured properties.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. An apparatus comprising:
a substrate;
integrated circuitry on a first side of the substrate; and
an array of pins extending through the substrate, the pins including first ends on the first side of the substrate and second ends protruding beyond a second side of the substrate opposite the first side.

2. The apparatus of claim 1, wherein the integrated circuitry includes an application-specific integrated circuit (ASIC) with active semiconductor components.

3. The apparatus of claim 1, wherein the integrated circuitry includes passive circuitry to enable electrical coupling of the array of pins to external processor circuitry.

4. The apparatus of claim 1, wherein the second ends of the pins are exposed to enable the pins to contact structural features of semiconductor components fabricated on a semiconductor wafer, the semiconductor wafer distinct from the substrate.

5. The apparatus of claim 4, wherein the semiconductor components correspond to transistors not yet completely fabricated on the semiconductor wafer.

6. The apparatus of claim 4, wherein portions of the pins extending between the second side of the substrate and the exposed second ends are covered by a dielectric material.

7. The apparatus of claim 4, wherein first ones of the pins are to provide an excitation signal to the structural features and second ones of the pins are to capture a response signal based on a path of the excitation signal through the structural features.

8. The apparatus of claim 4, wherein the pins are distributed across a first area, the semiconductor wafer including regions corresponding to a plurality of semiconductor chips, a first one of the semiconductor chips corresponding to a second area of the semiconductor wafer, a size of the first area approximately equal to or greater than the second area.

9. The apparatus of claim 1, wherein adjacent ones of the pins are spaced less than 1 um apart.

10. The apparatus of claim 1, wherein the array of pins includes more than 10,000 pins.

11. The apparatus of claim 1, wherein the pins include cobalt.

12. The apparatus of claim 1, wherein the substrate is a semiconductor substrate.

13. The apparatus of claim 1, wherein the substrate is a dielectric substrate.

14. A method of manufacturing a probe to measure electrical properties of structural features on a semiconductor wafer, the method comprising:
fabricating circuitry on a first side of a substrate, the substrate different than the semiconductor wafer;
providing an array of metal vias extending through the substrate toward a second side of the substrate opposite the first side; and
removing a portion of the substrate to expose ends of the metal vias.

15. The method of claim 14, further including depositing a dielectric material on to sidewalls of the exposed ends of the metal vias.

16. The method of claim 14, wherein fabricating the circuitry includes fabricating an application-specific integrated circuit (ASIC) with active semiconductor components.

17. (canceled)

18. An apparatus comprising:
at least one memory;
machine readable instructions; and
processor circuitry to at least one of instantiate or execute the machine readable instructions to:
position an array of pins of a probe in contact with structural features fabricated on a semiconductor wafer;
cause a first set of the pins to deliver an excitation signal to the structural features;
capture, via a second set of the pins, a response signal based on a path of the excitation signal through the structural features;
determine measured properties of the structural features based on the response signal; and
identify a location of a potential defect in the structural features based on the measured properties.

19. The apparatus of claim 18, wherein the processor circuitry is to:
compare the measured properties to reference properties for the structural features; and
identify the location of the potential defect based on the comparison.

20. The apparatus of claim 19, wherein the structural features are first structural features, and the reference properties are based on separate measurements of second structural features distinct and separate from the first structural features, the second structural features having a same design as the first structural features.

21. The apparatus of claim 19, wherein the processor circuitry is to calculate the reference properties based on a numerical analysis of a design of the structural features.

22. The apparatus of claim 18, wherein the processor circuitry is to determine the measured properties based on a numerical analysis of a design of the structural features, the response signal defining a boundary condition for the numerical analysis.

23. The apparatus of claim 18, wherein the processor circuitry is to generate a notification indicating the potential defect.

24. The apparatus of claim 18, wherein the processor circuitry is to:
cause a first subset of the first set of pins to deliver a first portion of the excitation signal to the structural features at a first point in time; and
cause a second subset of the first set of pins to deliver a second portion of the excitation signal to the structural features at a second point in time after the first point in time.

25. The apparatus of claim 18, wherein the structural features correspond to parts of transistors, the processor circuitry to position the array of pins of the probe in contact with the structural features prior to completion of fabrication of the transistors.

26. The apparatus of claim 18, wherein the structural features are first structural features, the excitation signal is a first excitation signal, the response signal is a first response signal, and the measured properties are first measured properties, the processor circuitry to:
estimate second measured properties for second structural features based on the first measured properties, the second structural features fabricated on the semiconductor wafer after fabrication of the first structural features;
capture a second response signal based on a second excitation signal applied to the second structural features;
determine the second measured properties of the structural features based on the second response signal; and
compare the second measured properties to the estimation of the second measured properties.

27-44. (canceled)
